(19) United States
(12) Patent Application Publication
(10) Pub. No.: US 2024/0403163 A1
(43) Pub. Date: Dec. 5, 2024

(54) ERROR RATE MANAGEMENT IN NON-UNIFORM MEMORY ARRAYS

(71) Applicant: Western Digital Technologies, Inc., San Jose, CA (US)

(72) Inventors: Dimitri Houssameddine, Sunnyvale, CA (US); Kadriye Deniz Bozdag, Sunnyvale, CA (US); Raj Ramanujan, Federal Way, WA (US); Nicolas Irizarry, Folsom, CA (US)

(73) Assignee: Western Digital Technologies, Inc., San Jose, CA (US)

(21) Appl. No.: 18/360,398

(22) Filed: Jul. 27, 2023

Related U.S. Application Data
(60) Provisional application No. 63/505,300, filed on May 31, 2023.

(51) Int. Cl. G06F 11/10

(52) U.S. Cl. CPC G06F 11/1044; G06F 11/1016

(57) ABSTRACT

A plurality of control circuits are configured to individually connect to arrays that each include a plurality of non-volatile memory cells. Each non-volatile memory cell includes a programmable resistive element. Each control circuit is configured with an individual address offset. The plurality of control circuits are configured to: receive a read address from a memory controller in parallel, apply the respective individual address offsets to the read address to generate respective offset addresses, read portions of data from the respective offset addresses and send the data read from the offset addresses to the memory controller to perform Error Correction Code (ECC) decoding of the portions of data.

### CLAIM OF PRIORITY

The present application claims priority from U.S. Provisional Patent Application No. 63/505,300, entitled “ERROR RATE MANAGEMENT IN NON-UNIFORM MEMORY ARRAYS,” by Houssameddine et al., filed May 31, 2023, incorporated by reference herein in its entirety.

### BACKGROUND

Memory is widely used in various electronic devices such as cellular telephones, digital cameras, personal digital assistants, medical electronics, mobile computing devices, non-mobile computing devices, and data servers. Memory may comprise non-volatile memory or volatile memory. A non-volatile memory allows information to be stored and retained even when the non-volatile memory is not connected to a source of power (e.g., a battery).

One example of a non-volatile memory is magnetoresistive random access memory (MRAM), which uses magnetization to represent stored data, in contrast to some other memory technologies that use electronic charges to store data. Generally, MRAM includes a large number of magnetic memory cells formed on a semiconductor substrate, where each memory cell represents (at least) one bit of data. A bit of data is written to a memory cell by changing the direction of magnetization of a magnetic element within the memory cell, and a bit is read by measuring the resistance of the memory cell (low resistance typically represents a “0” bit and high resistance typically represents a “1” bit). As used herein, direction of magnetization is the direction that the magnetic moment is oriented.

Although MRAM is a promising technology, various phenomena may cause errors in data stored in MRAM. Error Correction Code (ECC) may be used to correct such errors. Correcting errors using ECC may require significant resources and take significant time. In some cases, data may have too many errors to correct using a given ECC scheme. Such data may be considered Uncorrectable by ECC or “UE” Managing the effects of errors in an efficient manner so that ECC corrected data can be reliably and efficiently generated from data stored in MRAM is challenging.

### BRIEF DESCRIPTION OF THE DRAWING

Like-numbered elements refer to common components in the different figures.

FIG. 1 is a block diagram of one embodiment of a memory system connected to a host.

FIG. 2 is a block diagram of one embodiment of a Front End Processor Circuit. In some embodiments, the Front End Processor Circuit is part of a Controller.

FIG. 3 is a block diagram of one embodiment of a Back End Processor Circuit. In some embodiments, the Back End Processor Circuit is part of a Controller.

FIG. 4 is a block diagram of one embodiment of a memory package.

FIG. 5 is a block diagram of one embodiment of a memory die.

FIGS. 6A and 6B illustrate an example of control circuits coupled to a memory structure through wafer-to-wafer bonding.

FIG. 7A depicts one embodiment of a portion of a memory array that forms a cross-point architecture in an oblique view.

FIGS. 7B and 7C respectively present side and top views of the cross-point structure in FIG. 7A.

FIG. 7D depicts an embodiment of a portion of a two level memory array that forms a cross-point architecture in an oblique view.

FIG. 8 illustrates an embodiment for the structure of an MRAM memory cell.

FIG. 9 illustrates an embodiment for an MRAM memory cell design as it would be implemented in a cross-point array in more detail.

FIGS. 10A and 10B illustrate the writing of an MRAM memory cell by use of a spin torque transfer (STT) mechanism.

FIGS. 11A and 11B illustrate embodiments for the incorporation of threshold switching selectors into an MRAM memory array having a cross-point architecture.

FIGS. 12 and 13 show a set of waveforms respectively for the current and the voltage for the layer 1 cell of FIGS. 11A and 11B in a read operation.

FIG. 14 shows an example of the voltage of the MRAM device as the threshold switching selector switches from an off state to an on state.

FIG. 15 shows an example of the current in the MRAM device as the threshold switching selector switches from an off state to an on state.

FIG. 16 shows examples of memory cells at different locations in a module.

FIGS. 17A-D show an example structure that includes multiple media.

FIGS. 18A-B show examples of reading media using a common address.

FIG. 19 shows an example of using different individual address offsets in each media.

FIG. 20 shows an example of sending different read addresses to each media.

FIG. 21 shows an example of using offsets to read different modules of the same media at different locations.

FIG. 22 shows an example of a method that includes applying address offsets to generate offset addresses.

FIG. 23 shows an example of a method that includes reading portions of data from first and second offset addresses.

FIG. 24 shows an example of a method that includes writing data at offset addresses.

### DETAILED DESCRIPTION

In a memory array with a cross-point type architecture, a first set of conductive lines run across the surface of a substrate and a second set of conductive lines are formed over the first set of conductive lines, running over the substrate in a direction perpendicular to the first set of conductive lines. The memory cells are located at the cross-point junctions of the two sets of conductive lines. Embodiments for the memory cells can include a programmable resistance element, such as an MRAM memory cell, connected in series with a selector switch. One type of selector switch is threshold switching selector, such as ovonic threshold switch, which can be implemented in a small amount of area, and without need of an additional control line, relative to other switching elements, such as a transistor. If a voltage is above a certain level, the threshold voltage is applied across a threshold switching selector, it will switch to a conducting state.

Data may be read from multiple MRAM memory cells and sent to ECC circuits for decoding. Errors may occur in such data for a number of reasons. Data from MRAM memory cells in some structures may be affected by “snapback disturbs” caused by a relatively high current referred to as “snapback current.” Snapback current may be affected by a number of factors including the distance of a given memory cell from word line and bit line drivers (e.g., the length of electrical connections from the memory cell to a word line driver and to a bit line driver) which may cause snapback-related effects to be non-uniform. For example, memory cells nearer to word line and/or bit line drivers (near cells) may have higher snapback current and may be more affected by snapback disturbs than memory cells that are farther away from word line and/or bit line drivers (far cells). As a result, data from near memory cells may have higher error rates than data from far memory cells. Other phenomena may also have non-uniform effects.

In an embodiment, data that is ECC encoded and decoded together (e.g., as an ECC codeword) may be located at different respective locations in different arrays (e.g., some data in near cells and some in far cells) so that error rates of memory cells at multiple locations are combined, which may provide an averaged error rate and may mitigate effects of non-uniform error rates in memory arrays. This may provide relatively uniform error rates across different ECC codewords so that the risk of UE is relatively low. For example, different media (e.g., different memory dies) may apply different address offsets to an address so that each media accesses a respective memory array at a different location.

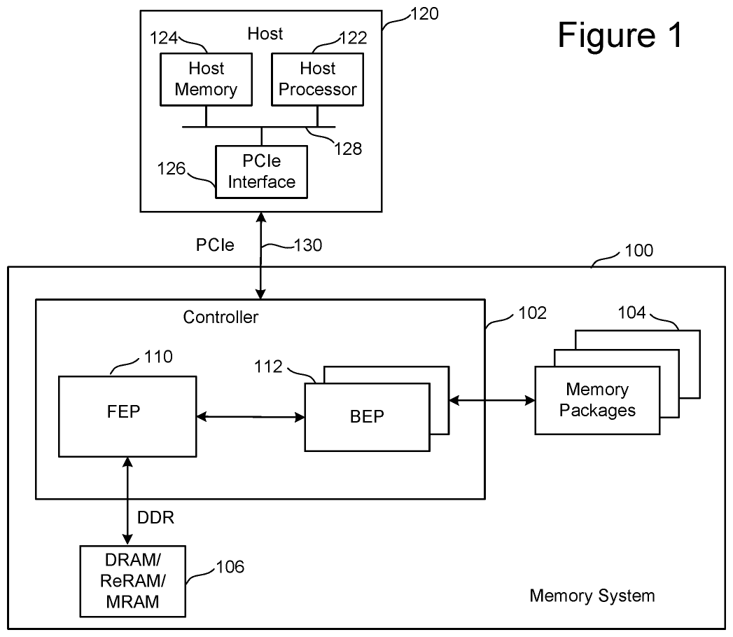

FIG. 1 is a block diagram of one embodiment of a memory system 100 connected to a host 120. Memory system 100 can implement the technology presented herein for managing error rates. Many different types of memory systems can be used with the technology proposed herein. Example memory systems include solid state drives (“SSDs”), memory cards including dual in-line memory modules (DIMMs) for DRAM replacement, and embedded memory devices; however, other types of memory systems can also be used.

Memory system 100 of FIG. 1 comprises a controller 102, non-volatile memory 104 for storing data, and local memory (e.g., DRAM/ReRAM/MRAM) 106. Controller 102 comprises a Front End Processor (FEP) circuit 110 and one or more Back End Processor (BEP) circuits 112. In one embodiment FEP circuit 110 is implemented on an Application Specific Integrated Circuit (ASIC). In one embodiment, each BEP circuit 112 is implemented on a separate ASIC. In other embodiments, a unified controller ASIC can combine both the front end and back end functions. The ASICs for each of the BEP circuits 112 and the FEP circuit 110 are implemented on the same semiconductor such that the controller 102 is manufactured as a System on a Chip (“SoC”). FEP circuit 110 and BEP circuit 112 both include their own processors. In one embodiment, FEP circuit 110 and BEP circuit 112 work as a master slave configuration where the FEP circuit 110 is the master and each BEP circuit 112 is a slave. For example, FEP circuit 110 implements a Flash Translation Layer (FTL) or Media Management Layer (MML) that performs memory management (e.g., garbage collection, wear leveling, etc.), logical to physical address translation, communication with the host, management of DRAM (local volatile memory) and management of the overall operation of the SSD (or other non-volatile storage system). The BEP circuit 112 manages memory operations in the memory packages/die at the request of FEP circuit 110. For example, the BEP circuit 112 can carry out the read, erase, and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages.

In one embodiment, non-volatile memory 104 comprises a plurality of memory packages. Each memory package includes one or more memory die. Therefore, controller 102 is connected to one or more non-volatile memory die. In one embodiment, each memory die in the memory packages 104 utilize NAND flash memory (including two dimensional NAND flash memory and/or three dimensional NAND flash memory). In other embodiments, the memory package can include other types of memory, such as storage class memory (SCM) based on resistive random access memory (such as ReRAM, MRAM, FeRAM or RRAM) or a phase change memory (PCM). In other embodiments, the BEP or FEP can be included on the memory die.

Controller 102 communicates with host 120 via an interface 130 that implements a protocol such as, for example, NVM Express (NVMe) or Compute Express Link (CXL) over PCI Express (PCIe) or using JEDEC standard Double Data Rate or Low-Power Double Data Rate (DDR or LPDDR) interface such as DDR5 or LPDDR5. For working with memory system 100, host 120 includes a host processor 122, host memory 124, and a PCIe interface 126 connected along bus 128. Host memory 124 is the host's physical memory, and can be DRAM, SRAM, MRAM, non-volatile memory, or another type of storage. Host 120 is external to and separate from memory system 100. In one embodiment, memory system 100 is embedded in host 120.

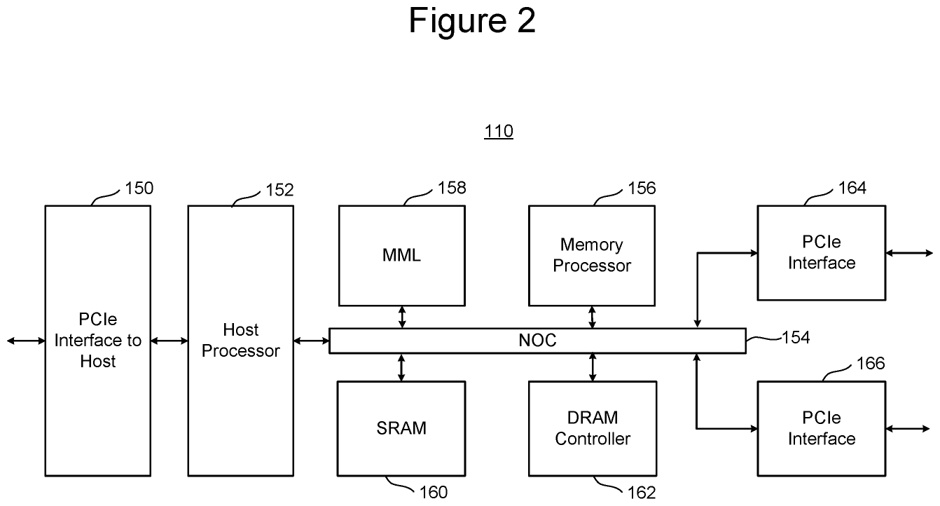

FIG. 2 is a block diagram of one embodiment of FEP circuit 110. FIG. 2 shows a PCIe interface 150 to communicate with host 120 and a host processor 152 in communication with that PCIe interface. The host processor 152 can be any type of processor known in the art that is suitable for the implementation. Host processor 152 is in communication with a network-on-chip (NOC) 154. A NOC is a communication subsystem on an integrated circuit, typically between cores in a SoC. NOCs can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, SRAM 160 and a DRAM controller 162. The DRAM controller 162 is used to operate and communicate with the DRAM (e.g., DRAM 106). SRAM 160 is local RAM memory used by memory processor 156. Memory processor 156 is used to run the FEP circuit and perform the various memory operations. Also, in communication with the NOC are two PCIe Interfaces 164 and 166. In the embodiment of FIG. 2, the SSD controller will include two BEP circuits 112; therefore, there are two PCIe Interfaces 164/166. Each PCIe Interface communicates with one of the BEP circuits 112. In other embodiments, there can be more or less than two BEP circuits 112; therefore, there can be more than two PCIe Interfaces.

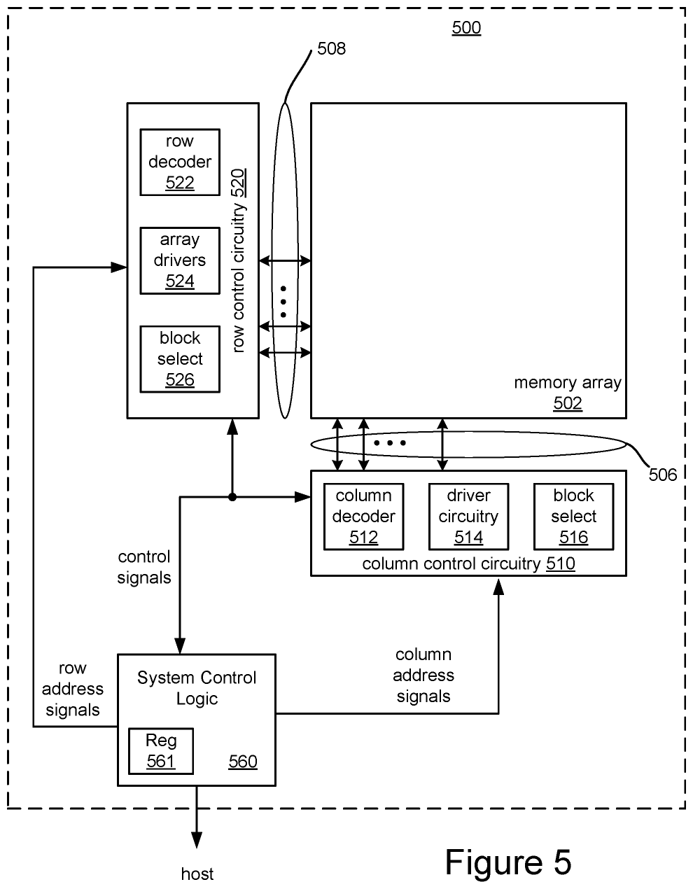

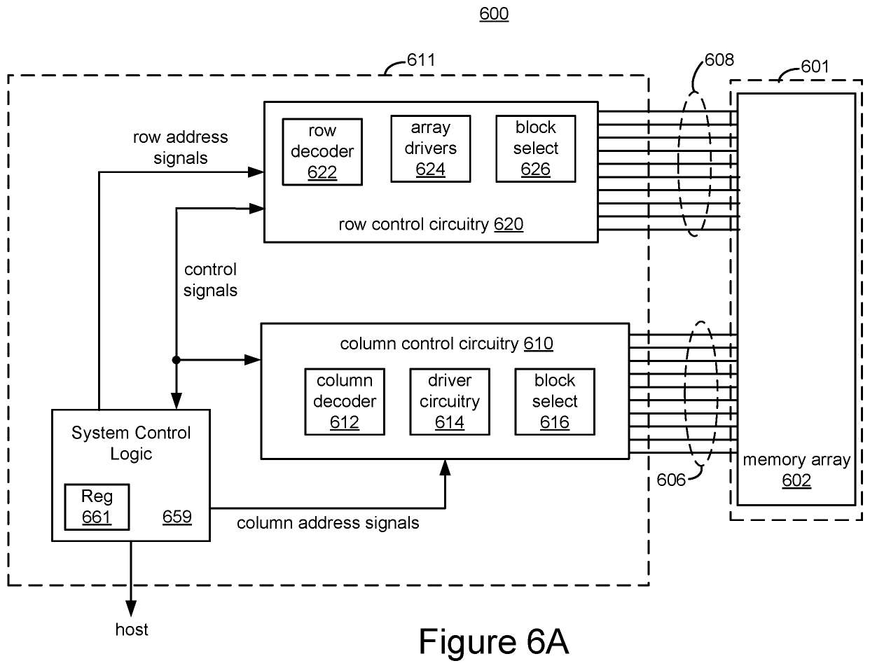

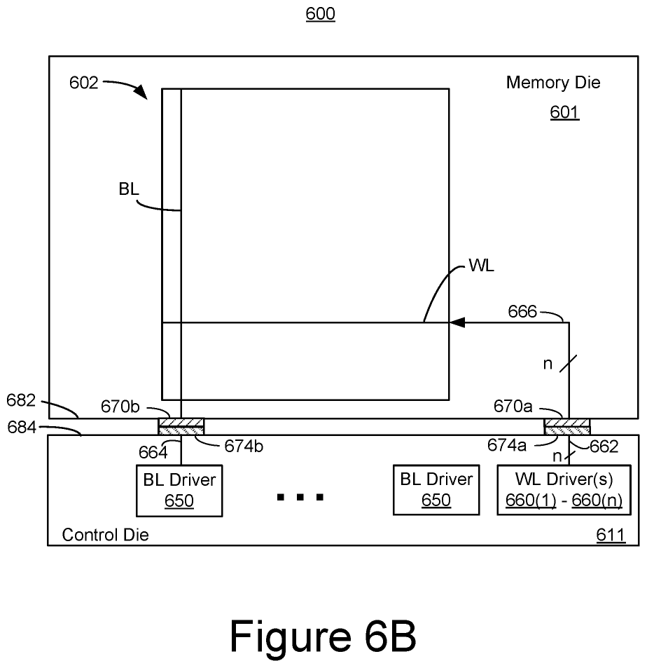

FEP circuit 110 can also include a Flash Translation Layer (FTL) or, more generally, a Media Management Layer (MML) 158 that performs memory management (e.g., garbage collection, wear leveling, load balancing, etc.), logical to physical address translation, communication with the host, management of DRAM (local volatile memory) and management of the overall operation of the SSD or other non-volatile storage system. The media management layer MML 158 may be integrated as part of the memory management that may handle memory errors and interfacing with the host. In particular, MML may be a module in the FEP circuit 110 and may be responsible for the internals of memory management. In particular, the MML 158 may include an algorithm in the memory device firmware which translates writes from the host into writes to the memory structure (e.g., 502/602 of FIGS. 5 and 6 below) of a die. The MML 158 may be needed because: 1) the memory may have limited endurance; 2) the memory structure may only be written in multiples of pages; and/or 3) the memory structure may not be written unless it is erased as a block. The MML 158 understands these potential limitations of the memory structure which may not be visible to the host. Accordingly, the MML 158 attempts to translate the writes from host into writes into the memory structure.

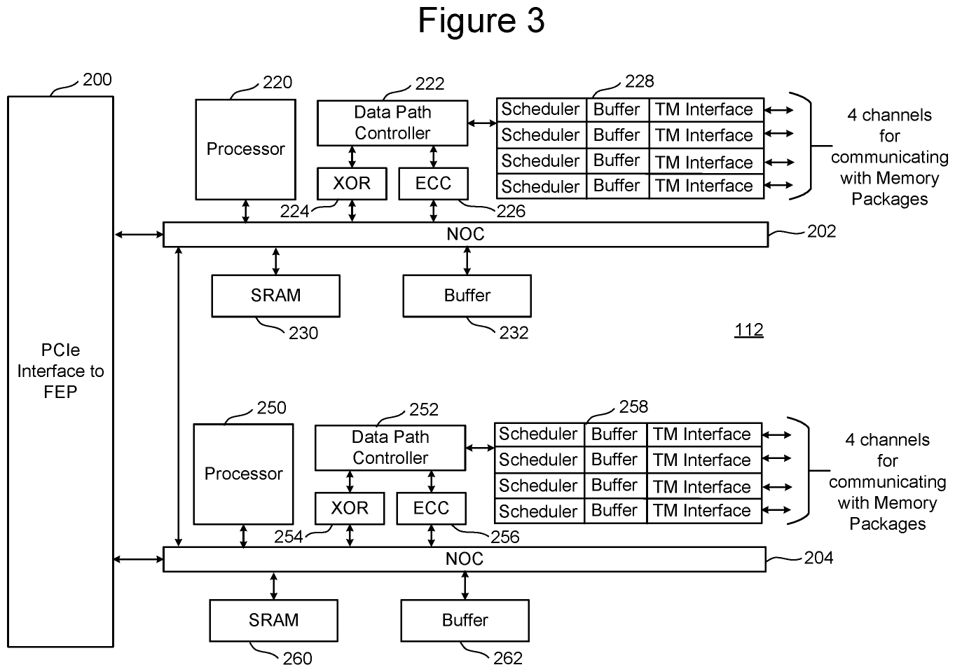

FIG. 3 is a block diagram of one embodiment of the BEP circuit 112. FIG. 3 shows a PCIe Interface 200 for communicating with the FEP circuit 110 (e.g., communicating with one of PCIe Interfaces 164 and 166 of FIG. 2). PCIe Interface 200 is in communication with two NOCs 202 and 204. In one embodiment the two NOCs can be combined into one large NOC. Each NOC (202/204) is connected to SRAM (230/260), a buffer (232/262), processor (220/250), and a data path controller (222/252) via an XOR engine (224/254) and an ECC engine (226/256). The ECC engines 226/256 are used to perform error correction, as known in the art. The XOR engines 224/254 are used to XOR the data so that data can be combined and stored in a manner that can be recovered in case there is a programming error. Data path controller 222 is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer, and TM Interface for each of the channels. The processor can be any standard processor known in the art. The data path controllers 222/252 can be a processor, FPGA, microprocessor, or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

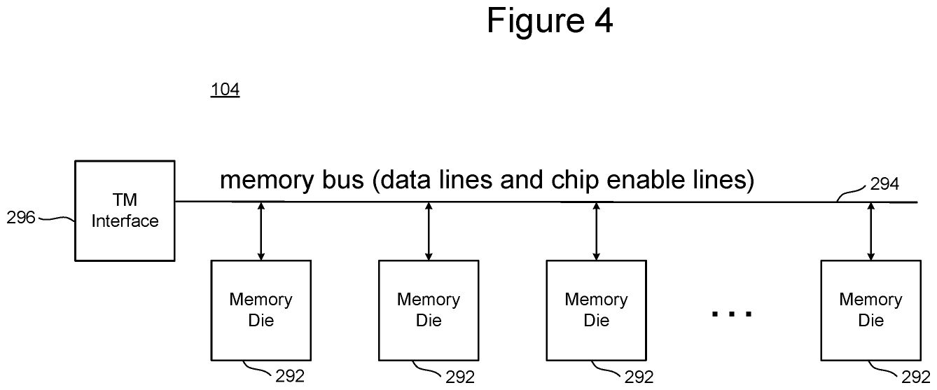

FIG. 4 is a block diagram of one embodiment of a memory package 104 that includes a plurality of memory die 292 connected to a memory bus (data lines and chip enable lines) 294. The memory bus 294 connects to a Toggle Mode Interface 296 for communicating with the TM Interface of a BEP circuit 112 (see e.g., FIG. 3). In some embodiments, the memory package can include a small controller connected to the memory bus and the TM Interface. The memory package can have one or more memory die. In one embodiment, each memory package includes eight or 16 memory die; however, other numbers of memory die can also be implemented. In another embodiment, the Toggle Interface is instead JEDEC standard DDR or LPDDR with or without variations such as relaxed time-sets or smaller page size. The technology described herein is not limited to any particular number of memory die.

FIG. 5 is a block diagram that depicts one example of a memory system 500 that can implement the technology described herein. Memory system 500 includes a memory array 502 that can include any of memory cells described in the following. The array terminal lines of memory array 502 include the various layer(s) of word lines organized as rows, and the various layer(s) of bit lines organized as columns. However, other orientations can also be implemented. Memory system 500 includes row control circuitry 520, whose outputs 508 are connected to respective word lines of the memory array 502. Row control circuitry 520 receives a group of M row address signals and one or more various control signals from system control logic circuit 560, and typically may include such circuits as row decoders 522, array terminal drivers 524 (e.g., word line drivers), and block select circuitry 526 for both reading and writing operations. Memory system 500 also includes column control circuitry 510 whose input/outputs 506 are connected to respective bit lines of the memory array 502. Although only a single block is shown for memory array 502, a memory die can include multiple arrays or “tiles” that can be individually accessed. Column control circuitry 510 receives a group of N column address signals and one or more various control signals from System Control Logic 560, and typically may include such circuits as column decoders 512, array terminal receivers or drivers 514 (e.g., bit line drivers), block select circuitry 516, as well as read/write circuitry, and I/O multiplexers.

System control logic 560 receives data and commands from a host and provides output data and status to the host. In other embodiments, system control logic 560 receives data and commands from a separate controller circuit and provides output data to that controller circuit, with the controller circuit communicating with the host. In some embodiments, the system control logic 560 can include a state machine that provides die-level control of memory operations. In one embodiment, the state machine is programmable by software. In other embodiments, the state machine does not use software and is completely implemented in hardware (e.g., electrical circuits). In another embodiment, the state machine is replaced by a micro-controller, with the micro-controller either on or off the memory chip. The system control logic 560 can also include a power control module, which controls the power and voltages supplied to the rows and columns of the memory array 502 during memory operations and may include charge pumps and regulator circuit for creating regulating voltages. System control logic 560 may include one or more state machines, registers and other control logic for controlling the operation of memory system 500. FIG. 5 illustrates such registers at 561, which, for example, can be used to store data such as offsets that may be used when accessing (e.g., reading or writing) memory cells of memory array 502. In some embodiments, all of the elements of memory system 500, including the system control logic 560, can be formed as part of a single die. In other embodiments, some or all of the system control logic 560 can be formed on a different die.

For purposes of this document, the phrase “one or more control circuits” can include a controller, a state machine, a micro-controller and/or other control circuitry as represented by the system control logic 560, or other analogous circuits that are used to control non-volatile memory.

In one embodiment, memory structure 502 comprises a three dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping.

In another embodiment, memory structure 502 comprises a two dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 502 is not limited to the examples above. Many different types of memory array architectures or memory technologies can be used to form memory structure 326. No particular non-volatile memory technology is required for purposes of the new claimed embodiments proposed herein. Other examples of suitable technologies for memory cells of the memory structure 502 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 502 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data using magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a programming current pulse. Note that the use of “pulse” in this document does not require a square pulse but includes a (continuous or non-continuous) vibration or burst of sound, current, voltage light, or other wave. Said memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 5 can be grouped into two parts, the structure of memory structure 502 of the memory cells and the peripheral circuitry, including all of the other elements. An important characteristic of a memory circuit is its capacity, which can be increased by increasing the area of the memory die of memory system 500 that is given over to the memory structure 502; however, this reduces the area of the memory die available for the peripheral circuitry. This can place quite severe restrictions on these peripheral elements. For example, the need to fit sense amplifier circuits within the available area can be a significant restriction on sense amplifier design architectures. With respect to the system control logic 560, reduced availability of area can limit the available functionalities that can be implemented on-chip. Consequently, a basic trade-off in the design of a memory die for the memory system 500 is the amount of area to devote to the memory structure 502 and the amount of area to devote to the peripheral circuitry.

Another area in which the memory structure 502 and the peripheral circuitry are often at odds is in the processing involved in forming these regions, since these regions often involve differing processing technologies and the trade-off in having differing technologies on a single die. For example, when the memory structure 502 is NAND flash, this is an NMOS structure, while the peripheral circuitry is often CMOS based. For example, elements such sense amplifier circuits, charge pumps, logic elements in a state machine, and other peripheral circuitry in system control logic 560 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 5 onto separately formed dies that are then bonded together. More specifically, the memory structure 502 can be formed on one die and some or all of the peripheral circuitry elements, including one or more control circuits, can be formed on a separate die. For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate die. This allows each of the memory die to be optimized individually according to its technology. For example, a NAND memory die can be optimized for an NMOS based memory array structure, without worrying about the CMOS elements that have now been moved onto a separate peripheral circuitry die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other memory circuit. Although the following will focus on a bonded memory circuit of one memory die and one peripheral circuitry die, other embodiments can use more die, such as two memory die and one peripheral circuitry die, for example.

FIGS. 6A and 6B shows an alternative arrangement to that of FIG. 5, which may be implemented using wafer-to-wafer bonding to provide a bonded die pair for memory system 600. FIG. 6A shows an example of the peripheral circuitry, including control circuits, formed in a peripheral circuit or control die 611 coupled to memory structure 602 formed in memory die 601. As with 502 of FIG. 5, the memory die 601 can include multiple independently accessible arrays or “tiles”. Common components are labelled similarly to FIG. 5 (e.g., 502 is now 602, 510 is now 610, and so on). It can be seen that system control logic 659, row control circuitry 620, and column control circuitry 610 (which may be formed by a CMOS process) are located in control die 611. Additional elements, such as functionalities from controller 102, can also be moved into the control die 611. System control logic 659, row control circuitry 620, and column control circuitry 610 may be formed by a common process (e.g., CMOS process), so that adding elements and functionalities more typically found on a memory controller 102 may require few or no additional process steps (i.e., the same process steps used to fabricate controller 102 may also be used to fabricate system control logic 659, row control circuitry 620, and column control circuitry 610). Thus, while moving such circuits from a die such as memory die of memory system 500 may reduce the number of steps needed to fabricate such a die, adding such circuits to a die such as control die 611 may not require any additional process steps.

FIG. 6A shows column control circuitry 610 on the control die 611 coupled to memory structure 602 on the memory die 601 through electrical paths 606. For example, electrical paths 606 may provide electrical connection between column decoder 612, driver circuitry 614, and block select 616 and bit lines of memory structure 602. Electrical paths may extend from column control circuitry 610 in control die 611 through pads on control die 611 that are bonded to corresponding pads of the memory die 601, which are connected to bit lines of memory structure 602. Each bit line of memory structure 602 may have a corresponding electrical path in electrical paths 606, including a pair of bonded pads, which connects to column control circuitry 610. Similarly, row control circuitry 620, including row decoder 622, array drivers 624, and block select 626, are coupled to memory structure 602 through electrical paths 608. Each electrical path 608 may correspond to a word line, dummy word line, or select gate line. Additional electrical paths may also be provided between control die 611 and memory die 601.

FIG. 6B is a block diagram showing more detail on the arrangement of one embodiment of the integrated memory assembly 600 formed by a bonded die pair. Memory die 601 contains an array 602 of memory cells. The memory die 601 may have additional arrays (e.g., multiple modules, each including an array). One representative bit line (BL) and representative word line (WL) 666 are depicted for array 602. There may be thousands or tens of thousands of such bit lines per each array 602. In one embodiment, an array represents a group of connected memory cells that share a common set of unbroken word lines and unbroken bit lines.

Control die 611 includes a number of bit line drivers 650. Each bit line driver 650 is connected to one bit line or may be connected to multiple bit lines in some embodiments. The control die 611 includes a number of word line drivers 660(1)-660(n). The word line drivers 660 are configured to provide voltages to word lines. In this example, there are “n” word lines per array or plane memory cells. If the memory operation is a program or read, one word line within the selected block is selected for the memory operation, in one embodiment. If the memory operation is an erase, all of the word lines within the selected block are selected for the erase, in one embodiment. The word line drivers 660 provide voltages to the word lines in memory die 601. As discussed above with respect to FIG. 6A, the control die 611 may also include charge pumps, voltage generators, and the like that are not represented in FIG. 6B, which may be used to provide voltages for the word line drivers 660 and/or the bit line drivers 650.

The memory die 601 has a number of bond pads 670a, 670b on a first major surface 682 of memory die 601. There may be “n” bond pads 670a, to receive voltages from a corresponding “n” word line drivers 660(1)-660(n). There may be one bond pad 670b for each bit line associated with array 602. The reference numeral 670 will be used to refer in general to bond pads on major surface 682.

In some embodiments, each data bit and each parity bit of a codeword are transferred through a different bond pad pair 670b, 674b. The bits of the codeword may be transferred in parallel over the bond pad pairs 670b, 674b. This provides for a very efficient data transfer relative to, for example, transferring data between the memory controller 102 and the integrated memory assembly 600. For example, the data bus between the memory controller 102 and the integrated memory assembly 600 may, for example, provide for eight, sixteen, 32 or more bits to be transferred in parallel. However, the data bus between the memory controller 102 and the integrated memory assembly 600 is not limited to these examples. Such ECC may be implemented on the memory die in some embodiments.

The control die 611 has a number of bond pads 674a, 674b on a first major surface 684 of control die 611. There may be “n” bond pads 674a, to deliver voltages from a corresponding “n” word line drivers 660(1)-660(n) to memory die 601. There may be one bond pad 674b for each bit line associated with array 602. The reference numeral 674 will be used to refer in general to bond pads on major surface 682. Note that there may be bond pad pairs 670a/674a and bond pad pairs 670b/674b. In some embodiments, bond pads 670 and/or 674 are flip-chip bond pads.

In one embodiment, the pattern of bond pads 670 matches the pattern of bond pads 674. Bond pads 670 are bonded (e.g., flip chip bonded) to bond pads 674. Thus, the bond pads 670, 674 electrically and physically couple the memory die 601 to the control die 611. Also, the bond pads 670, 674 permit internal signal transfer between the memory die 601 and the control die 611. Thus, the memory die 601 and the control die 611 are bonded together with bond pads. Although FIG. 6A depicts one control die 611 bonded to one memory die 601, in another embodiment one control die 611 is bonded to multiple memory dies 601.

Herein, “internal signal transfer” means signal transfer between the control die 611 and the memory die 601. The internal signal transfer permits the circuitry on the control die 611 to control memory operations in the memory die 601. Therefore, the bond pads 670, 674 may be used for memory operation signal transfer. Herein, “memory operation signal transfer” refers to any signals that pertain to a memory operation in a memory die 601. A memory operation signal transfer could include, but is not limited to, providing a voltage, providing a current, receiving a voltage, receiving a current, sensing a voltage, and/or sensing a current.

The bond pads 670, 674 may be formed for example of copper, aluminum, and alloys thereof. There may be a liner between the bond pads 670, 674 and the major surfaces (682, 684). The liner may be formed for example of a titanium/titanium nitride stack. The bond pads 670, 674 and liner may be applied by vapor deposition and/or plating techniques. The bond pads and liners together may have a thickness of 720 nm, though this thickness may be larger or smaller in further embodiments.

Metal interconnects and/or vias may be used to electrically connect various elements in the dies to the bond pads 670, 674. Several conductive pathways, which may be implemented with metal interconnects and/or vias are depicted. For example, a sense amplifier may be electrically connected to bond pad 674b by pathway 664. Relative to FIG. 6A, the electrical paths 606 can correspond to pathway 664, bond pads 674b, and bond pads 670b. There may be thousands of such sense amplifiers, pathways, and bond pads. Note that the BL does not necessarily make direct connection to bond pad 670b. The word line drivers 660 may be electrically connected to bond pads 674a by pathways 662. Relative to FIG. 6A, the electrical paths 608 can correspond to the pathway 662, the bond pads 674a, and bond pads 670a. Note that pathways 662 may comprise a separate conductive pathway for each word line driver 660(1)-660(n). Likewise, a there may be a separate bond pad 674a for each word line driver 660(1)-660(n). The word lines in block 2 of the memory die 601 may be electrically connected to bond pads 670a by pathways 664. In FIG. 6B, there are “n” pathways 664, for a corresponding “n” word lines in a block. There may be separate pair of bond pads 670a, 674a for each pathway 664.

Relative to FIG. 5, the on-die control circuits of FIG. 6A can also include addition functionalities within its logic elements, both more general capabilities than are typically found in the memory controller 102 and some CPU capabilities, but also application specific features.

In the following, system control logic 560/660, column control circuitry 510/610, row control circuitry 520/620, and/or controller 102 (or equivalently functioned circuits), in combination with all or a subset of the other circuits depicted in FIG. 5 or on the control die 611 in FIG. 6A and similar elements in FIG. 5, can be considered part of the one or more control circuits that perform the functions described herein. The control circuits can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In the following discussion, the memory array 502/602 of FIGS. 5 and 6A will mainly be discussed in the context of a cross-point architecture, although much of the discussion can be applied more generally. In a cross-point architecture, a first set of conductive lines or wires, such as word lines, run in a first direction relative to the underlying substrate and a second set of conductive lines or wires, such a bit lines, run in a second direction relative to the underlying substrate. The memory cells are sited at the intersection of the word lines and bit lines. The memory cells at these cross-points can be formed according to any of a number of technologies, including those described above. The following discussion will mainly focus on embodiments based on a cross-point architecture using MRAM memory cells.

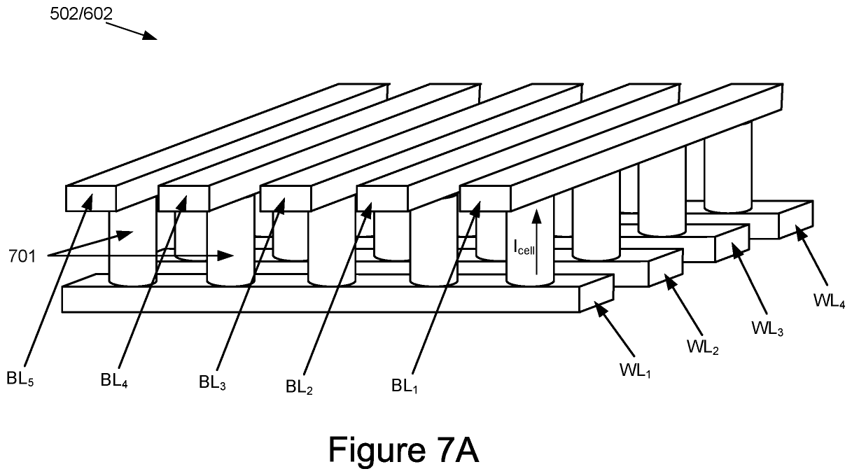

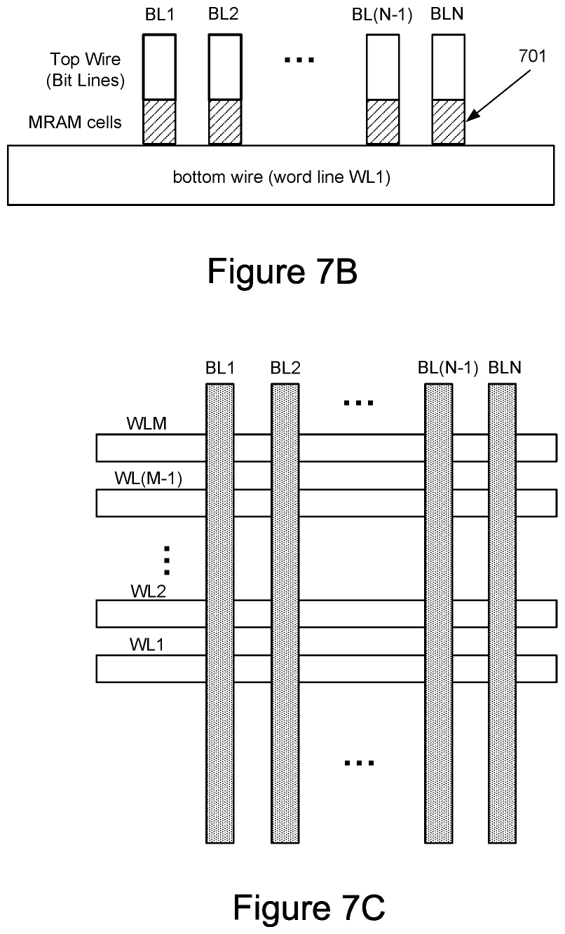

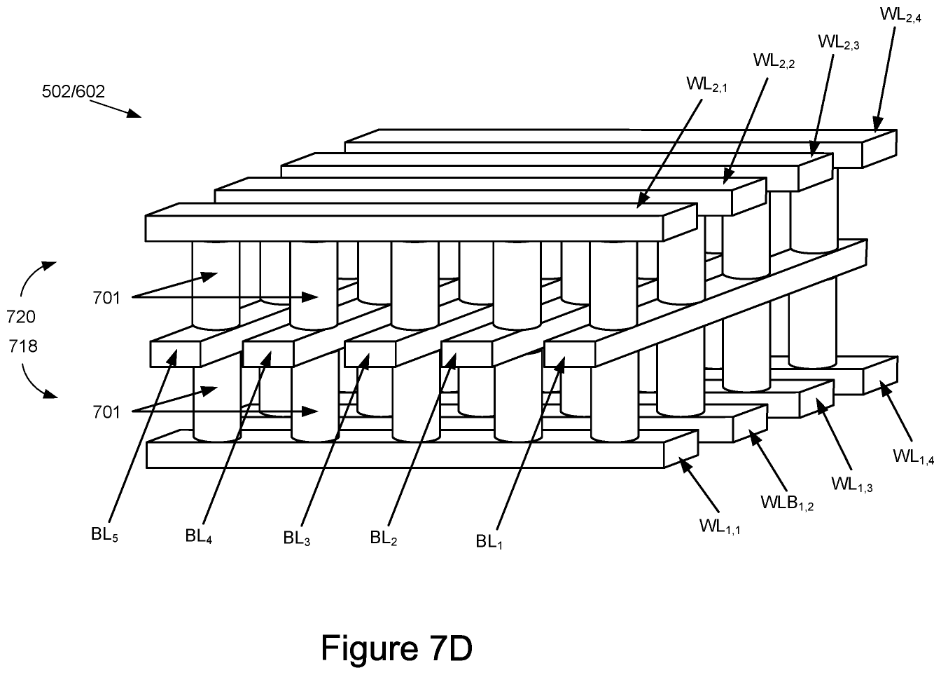

FIG. 7A depicts one embodiment of a portion of a memory array that forms a cross-point architecture in an oblique view. Memory array 502/602 of FIG. 7A is one example of an implementation for memory array 502 in FIG. 5 or 602 in FIG. 6A, where a memory die can include multiple such array structures. The bit lines BL₁-BL₅ are arranged in a first direction (represented as running into the page) relative to an underlying substrate (not shown) of the die and the word lines WL₁-WL₅ are arranged in a second direction perpendicular to the first direction (across the page). FIG. 7A is an example of a horizontal cross-point structure in which word lines WL₁-WL₅ and BL₁-BL₅ both run in a horizontal direction relative to the substrate, while the memory cells, two of which are indicated at 701, are oriented so that the current through a memory cell (such as shown at I_{cell}) runs in the vertical direction. In a memory array with additional layers of memory cells, such as discussed below with respect to FIG. 7D, there would be corresponding additional layers of bit lines and word lines.

As depicted in FIG. 7A, memory array 502/602 includes a plurality of memory cells 701. The memory cells 701 may include re-writeable memory cells, such as can be implemented using ReRAM, MRAM, PCM, FeRAM, or other material with a programmable resistance. The following discussion will focus on MRAM memory cells, although much of the discussion can be applied more generally. The current in the memory cells of the first memory level is shown as flowing upward as indicated by arrow I_{cell}, but current can flow in either direction, as is discussed in more detail in the following.

FIGS. 7B and 7C respectively present side and top views of the cross-point structure in FIG. 7A. The sideview of FIG. 7B shows one bottom wire, or word line, WL₁ and the top wires, or bit lines, BL₁-BLₙ. At the cross-point between each top wire and bottom wire is an MRAM memory cell, although PCM, FeRAM, ReRAM, or other technologies can be used. FIG. 7C is a top view illustrating the cross-point structure for M bottom wires WL₁-WL_{M} and N top wires BL₁-BL_{N}. In a binary embodiment, the MRAM cell at each cross-point can be programmed into one of two resistance states: high and low. More detail on embodiments for an MRAM memory cell design and techniques for their programming are given below.

The cross-point array of FIG. 7A illustrates an embodiment with one layer of word lines and bits lines, with the MRAM or other memory cells sited at the intersection of the two sets of conducting lines. To increase the storage density of a memory die, multiple layers of such memory cells and conductive lines can be formed. A 2-layer example is illustrated in FIG. 7D.

FIG. 7D depicts an embodiment of a portion of a two level memory array that forms a cross-point architecture in an oblique view. As in FIG. 7A, FIG. 7D shows a first layer 718 of memory cells 701 of an array 502/602 connected at the cross-points of the first layer of word lines WL_{1,1}-WL_{1,4} and bit lines BL₁-BL₅. A second layer of memory cells 720 is formed above the bit lines BL₁-BL₅ and between these bit lines and a second set of word lines WL_{2,1}-WL_{2,4}. Although FIG. 7D shows two layers, 718 and 720, of memory cells, the structure can be extended upward through additional alternating layers of word lines and bit lines. Depending on the embodiment, the word lines and bit lines of the array of FIG. 7D can be biased for read or program operations such that current in each layer flows from the word line layer to the bit line layer or the other way around. The two layers can be structured to have current flow in the same direction in each layer for a given operation, e.g. from bit line to word line for read, or to have current flow in the opposite directions, e.g. from word line to bit line for layer 1 read and from bit line to word line for layer 2 read.

The use of a cross-point architecture allows for arrays with a small footprint and several such arrays can be formed on a single die. The memory cells formed at each cross-point can be a resistive type of memory cell, where data values are encoded as different resistance levels. Depending on the embodiment, the memory cells can be binary valued, having either a low resistance state or a high resistance state, or multi-level cells (MLCs) that can have additional resistance intermediate to the low resistance state and high resistance state. The cross-point arrays described here can be used as the memory die 292 of FIG. 4, to replace local memory 106, or both. Resistive type memory cells can be formed according to many of the technologies mentioned above, such as ReRAM, FeRAM, PCM, or MRAM. The following discussion is presented mainly in the context of memory arrays using a cross-point architecture with binary valued MRAM memory cells, although much of the discussion is more generally applicable.

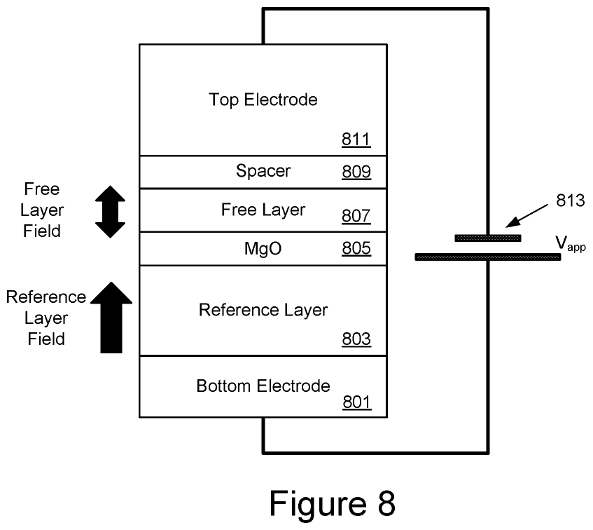

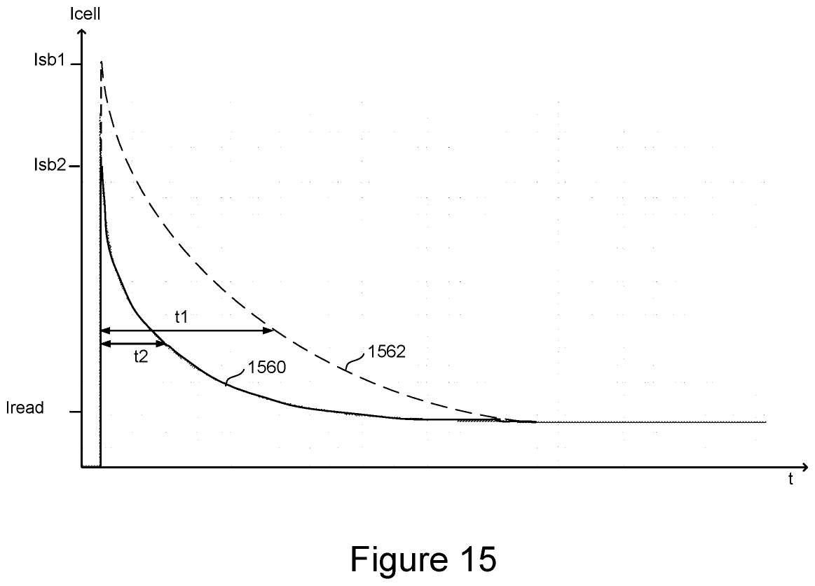

FIG. 8 illustrates an embodiment for the structure of an MRAM memory cell. A voltage being applied across the memory cell, between the memory cell's corresponding word line and bit line, is represented as a voltage source Vₐₚₚ 813. The memory cell includes a bottom electrode 801, a pair of magnetic layers (reference layer 803 and free layer 807) separated by a separation or tunneling layer of, in this example, magnesium oxide (MgO) 805, and then a top electrode 811 separated from the free layer 807 by a spacer 809. The state of the memory cell is based on the relative orientation of the magnetizations of the reference layer 803 and the free layer 807: if the two layers are magnetized in the same direction, the memory cell will be in a parallel (P) low resistance state (LRS); and if they have the opposite orientation, the memory cell will be in an anti-parallel (AP) high resistance state (HRS). An MLC embodiment would include additional intermediate states. The orientation of the reference layer 803 is fixed and, in the example of FIG. 15, is oriented upward. Reference layer 803 is also known as a fixed layer or pinned layer.

Data is written to an MRAM memory cell by programming the free layer 807 to either have the same orientation or opposite orientation. The reference layer 803 is formed so that it will maintain its orientation when programming the free layer 807. The reference layer 803 can have a more complicated design that includes synthetic anti-ferromagnetic layers and additional reference layers. For simplicity, the figures and discussion omit these additional layers and focus only on the fixed magnetic layer primarily responsible for tunneling magnetoresistance in the cell.

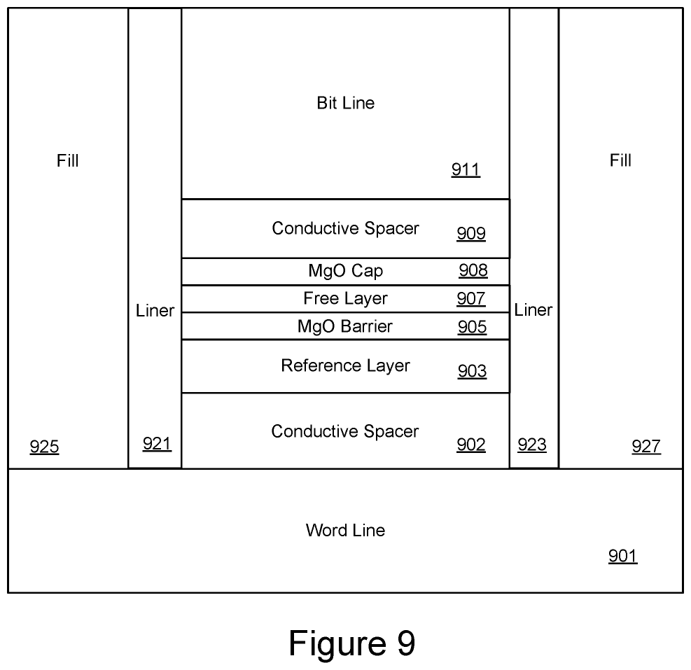

FIG. 9 illustrates an embodiment for an MRAM memory cell design as it would be implemented in a cross-point array in more detail. When placed in a cross-point array, the top and bottom electrodes of the MRAM memory cells will be two of the adjacent layers of wires of the array, for example the top and bottom wires of the two level or two deck array. In the embodiment shown here, the bottom electrode is the word line 901 and the top electron is the bit line 911 of the memory cell, but these can be reversed in some embodiments by reversing the orientation of the memory element. Between the word line 901 and bit line 911 are the reference layer 903 and free layer 907, which are again separated MgO barrier 905. In the embodiment shown in FIG. 9, a MgO cap 908 is also formed on top of the free layer 907 and a conductive spacer 909 is formed between the bit line 911 and the MgO cap 908. The reference layer 903 is separated from the word line 901 by another conductive spacer 902. On either side of the memory cell structure is a liner 921 and 923, where these can be part of the same structure, but appear separate in the cross-section of FIG. 9. To either side of the liner 921, 923 is shown some of fill material 925, 927 used to fill in the otherwise empty regions of the cross-point structure.

With respect to the free layer design 907, embodiments include CoFe or CoFeB Alloy with a thickness on the order ˜1-2 nm, where an Ir layer can be interspersed in the free layer close to MgO barrier 905 and the free layer 907 can be doped with Ta, W, or Mo. Embodiments for the reference layer 903 can include a bilayer of CoFeB and CoPt multilayer coupled with an Ir or Ru spacer 902. The MgO cap 908 is optional, but can be used to increase anisotropy of free layer 907. The conductive spacers can be conductive metals such as Ta, W, Ru, CN, TiN, and TaN, among others.

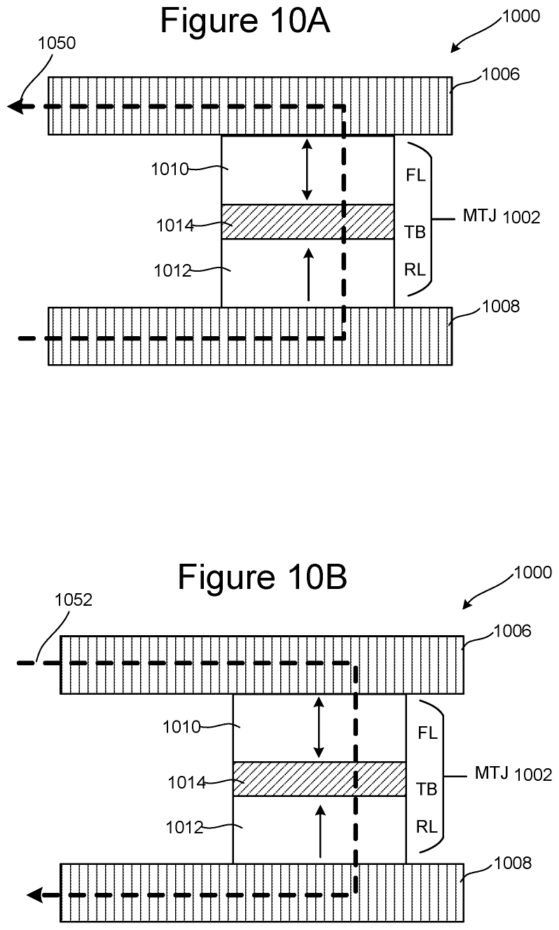

To sense a data state stored in an MRAM, a voltage is applied across the memory cell as represented by Vₐₚₚ to determine its resistance state. For reading an MRAM memory cell, the voltage differential Vₐₚₚ can be applied in either direction; however, MRAM memory cells have a directionality and, because of this, in some circumstances there is a preference for reading in one direction over the other. For example, the optimum current amplitude to write a bit into the AP (high resistance state, HRS) may be greater than that to write to the P (low resistance state) by 50% or more, so bit error rate (read disturb) is less probable if reading to AP (2AP). Some of these circumstances and the resultant directionality of a read are discussed below. The directionality of the biasing particularly enters into some embodiments for the programming of MRAM memory cells, as is discussed further with respect to FIGS. 10A and 10B.

The following discussion will mainly be discussed with respect to a perpendicular spin transfer torque MRAM memory cell, where the free layer 807/907 of FIGS. 8 and 9 comprises a switchable direction of magnetization that is perpendicular to the plane of the free layer. Spin transfer torque (“STT”) is an effect in which the orientation of a magnetic layer in a magnetic tunnel junction can be modified using a spin-polarized current. Charge carriers (such as electrons) have a property known as spin which is a small quantity of angular momentum intrinsic to the carrier. An electric current is generally unpolarized (e.g., consisting of 50% spin-up and 50% spin-down electrons). A spin polarized current is one with more electrons of either spin (e.g., a majority of spin-up electrons or a majority of spin-down electrons). By passing a current through a thick magnetic layer (the reference layer), a spin-polarized current can be produced. If this spin-polarized current is directed into a second magnetic layer (the free layer), angular momentum can be transferred to this second magnetic layer, changing the direction of magnetization of the second magnetic layer. This is referred to as spin transfer torque. FIGS. 10A and 10B illustrate the use of spin transfer torque to program or write to MRAM memory. Spin transfer torque magnetic random access memory (STT MRAM) has the advantages of lower power consumption and better scalability over MRAM variations such as toggle MRAM. Compared to other MRAM implementations, the STT switching technique requires relatively low power, virtually eliminates the problem of adjacent bit disturbs, and has more favorable scaling for higher memory cell densities (reduced MRAM cell size). The latter issue also favors STT MRAM where the free and reference layer magnetizations are orientated perpendicular to the film plane, rather than in-plane.

As the STT phenomenon is more easily described in terms of electron behavior, FIGS. 10A and 10B and their discussion are given in terms of electron current, where the direction of the write current is defined as the direction of the electron flow. Therefore, the term write current in reference to FIGS. 10A and 10B refers to an electron current. As electrons are negatively charged, the electron current will be in the opposite direction from the conventionally defined current, so that an electron current will flow from a lower voltage level towards a higher voltage level instead the conventional current flow of from a higher voltage level to a lower voltage level.

FIGS. 10A and 10B illustrate the writing of an MRAM memory cell by use a the STT mechanism, depicting a simplified schematic representation of an example of an STT-switching MRAM memory cell 1000 in which both the reference and free layer magnetization are in the perpendicular direction. Memory cell 1000 includes a magnetic tunnel junction (MTJ) 1002 comprising an upper ferromagnetic layer 1010, a lower ferromagnetic layer 1012, and a tunnel barrier (TB) 1014 as an insulating layer between the two ferromagnetic layers. In this example, upper ferromagnetic layer 1010 is the free layer FL and the direction of its magnetization can be switched. Lower ferromagnetic layer 1012 is the reference (or fixed) layer RL and the direction of its magnetization cannot be switched. When the magnetization in free layer 1010 is parallel to the magnetization in reference layer RL 1012, the resistance across the memory cell 1000 is relatively low. When the magnetization in free layer FL 1010 is anti-parallel to the magnetization in reference layer RL 1012, the resistance across memory cell 1000 is relatively high. The data (“0” or “1”) in memory cell 1000 is read by measuring the resistance of the memory cell 1000. In this regard, electrical conductors 1006/1008 attached to memory cell 1000 are utilized to read the MRAM data. By design, both the parallel and antiparallel configurations remain stable in the quiescent state and/or during a read operation (at sufficiently low read current).

For both the reference layer RL 1012 and free layer FL 1010, the direction of magnetization is in a perpendicular direction (i.e. perpendicular to the plane defined by the free layer and perpendicular to the plane defined by the reference layer). FIGS. 10A and 10B show the direction of magnetization of reference layer RL 1012 as up and the direction of magnetization of free layer FL 1010 as switchable between up and down, which is again perpendicular to the plane.

In one embodiment, tunnel barrier 1014 is made of Magnesium Oxide (MgO); however, other materials can also be used. Free layer 1010 is a ferromagnetic metal that possess the ability to change/switch its direction of magnetization. Multilayers based on transition metals like Co, Fe and their alloys can be used to form free layer 1010. In one embodiment, free layer 1010 comprises an alloy of Cobalt, Iron and Boron. Reference layer 1012 can be many different types of materials including (but not limited to) multiple layers of Cobalt and Platinum and/or an alloy of Cobalt and Iron.

To “set” the MRAM memory cell bit value (i.e., choose the direction of the free layer magnetization), an electron write current 1050 is applied from conductor 1008 to conductor 1006, as depicted in FIG. 10A. To generate the electron write current 1050, the top conductor 1006 is place at a higher voltage level than bottom conductor 1008, due to the negative charge of the electron. The electrons in the electron write current 1050 become spin-polarized as they pass through reference layer 1012 because reference layer 1012 is a ferromagnetic metal. When the spin-polarized electrons tunnel across the tunnel barrier 1014, conservation of angular momentum can result in the imparting of a spin transfer torque on both free layer 1010 and reference layer 1012, but this torque is inadequate (by design) to affect the magnetization direction of the reference layer 1012. Contrastingly, this spin transfer torque is (by design) sufficient to switch the magnetization orientation in the free layer 1010 to become parallel (P) to that of the reference layer 1012 if the initial magnetization orientation of the free layer 1010 was anti-parallel (AP) to the reference layer 1012, referred to as an anti-parallel-to-parallel (AP2P) write. The parallel magnetizations will then remain stable before and after such electron write current is turned off.

In contrast, if free layer 1010 and reference layer 1012 magnetizations are initially parallel, the direction of magnetization of free layer 1010 can be switched to become antiparallel to the reference layer 1012 by application of an electron write current of opposite direction to the aforementioned case. For example, electron write current 1052 is applied from conductor 1006 to conductor 1008, as depicted in FIG. 10B, by placing the higher voltage level on the lower conductor 1008. This will write a free layer 1010 in a P state to an AP state, referred to as a parallel-to-anti-parallel (P2AP) write. Thus, by way of the same STT physics, the direction of the magnetization of free layer 1010 can be deterministically set into either of two stable orientations by judicious choice of the electron write current direction (polarity).

The data (“0” or “1”) in memory cell 1000 can be read by measuring the resistance of the memory cell 1000. Low resistance typically represents a “0” bit and high resistance typically represents a “1” bit, although sometimes the alternate convention occurs. A read current can being applied across the memory cell (e.g., across the magnetic tunnel junction 1002) by applying an electron read current from conductor 1008 to conductor 1006, flowing as shown for 1050 in FIG. 10A (the “AP2P direction”); alternatively, the electron read current can be applied from conductor 1006 to conductor 1008, flowing as shown for 1052 in FIG. 10B (the “P2AP direction”). In a read operation, if the electron write current is too high, this can disturb data stored in a memory cell and change its state. For example, if electron read current uses the P2AP direction of FIG. 10B, too high of a current or voltage level can switch any memory cells in the low resistance P state into the high resistance AP state. Consequently, although the MRAM memory cell can be read in either direction, the directional nature of the write operation may make one read direction preferable over the other in various embodiments as the P2AP direction since more current is required to write the bit in that direction.

Although the discussion of FIGS. 10A and 10B was in the context of electron current for the read and write currents, the subsequent discussion will be in the context of conventional current unless otherwise specified.

Whether to read or write selected memory cells in the array structures of FIGS. 7A-7D, the bit line and word line corresponding to a selected memory cell are biased to place a voltage across the selected memory cell and induce the flow of electrons as illustrated with respect to FIG. 10A or 10B. This will also apply a voltage across non-selected memory cells of the array, which can induce currents in non-selected memory cells. Although this wasted power consumption can be mitigated to some degree by designing the memory cells to have relatively high resistance levels for both high and low resistance states, this will still result in increased current and power consumption as well as placing additional design constraints on the design of the memory cells and the array.

One approach to address this unwanted current leakage is to place a selector element in series with each MRAM or other resistive (e.g., ReRAM, PCM, and FeRAM) memory cell. For example, a select transistor can be placed in series with each resistive memory cell element in FIGS. 7A-7D so that the elements 701 are now a composite of a selector and a programmable resistance. Use of a transistor, however, requires the introduction of additional control lines to be able to turn on the corresponding transistor of a selected memory cell. Additionally, transistors will often not scale in the same manner as the resistive memory element, so that as memory arrays move to smaller sizes the use of transistor based selectors can be a limiting factor.

An alternate approach to selector elements is the use of a threshold switching selector device in series with the programmable resistive element. A threshold switching selector has a high resistance (in an off or non-conductive state) when it is biased to a voltage lower than its threshold voltage, and a low resistance (in an on or conductive state) when it is biased to a voltage higher than its threshold voltage. The threshold switching selector remains on until its current is lowered below a holding current, or the voltage is lowered below a holding voltage. When this occurs, the threshold switching selector returns to the off state. Accordingly, to program a memory cell at a cross-point, a voltage or current is applied which is sufficient to turn on the associated threshold switching selector and set or reset the memory cell; and to read a memory cell, the threshold switching selector similarly must be activated by being turned on before the resistance state of the memory cell can be determined. One set of examples for a threshold switching selector is an ovonic threshold switching material of an Ovonic Threshold Switch (OTS).

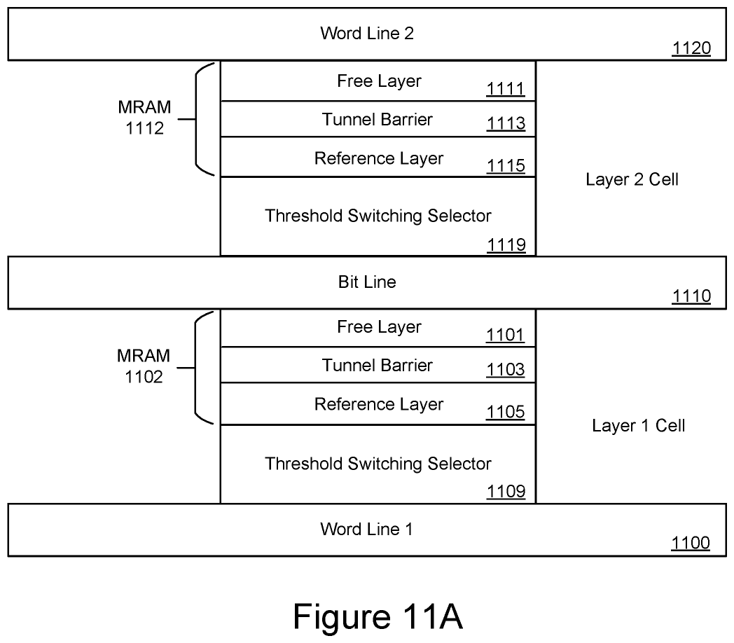

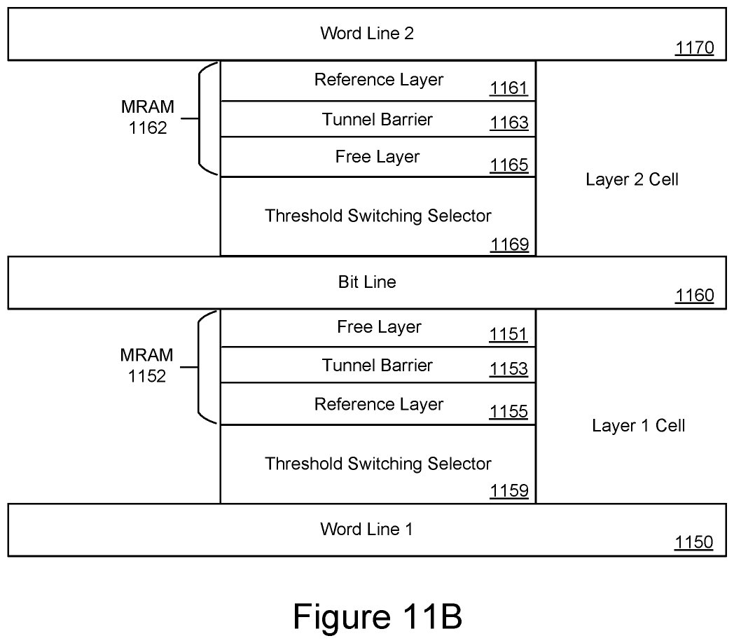

FIGS. 11A and 11B illustrate embodiments for the incorporation of threshold switching selectors into an MRAM memory array having a cross-point architecture. The examples of FIGS. 11A and 11B show two MRAM cells in a two layer cross-point array, such as shown in FIG. 7D, but in a side view. FIGS. 11A and 11B show a lower first conducting line of word line 1 1100, an upper first conducting line of word line 2 1120, and an intermediate second conducting line of bit line 1110. In these figures, all of these lines are shown running left to right across the page for ease of presentation, by in a cross-point array they would be more accurately represented as represented in the oblique view of FIG. 7D where the word lines, or first conducting lines or wires, run in one direction parallel to the surface of the underlying substrate and the bit lines, or second conducting lines or wires, run in a second direction parallel to the surface to the substrate that is largely orthogonal to the first direction. The MRAM memory cells are also represented in a simplified form, showing only the reference layer, free layer, and the intermediate tunnel barrier, but in an actual implementation would typically include the additional structure described above with respect to FIG. 9.

An MRAM cell 1102 including free layer 1101, tunnel barrier 1103, and reference layer 1105 is formed above the threshold switching selector 1109, where this series combination of the MRAM device 1102 and the threshold switching selector 1109 together form the layer 1 cell between the bit line 1110 and word line 1 1100. The series combination of the MRAM device 1102 and the threshold switching selector 1109 operate as largely as described above with respect to FIGS. 10A and 10B when the threshold switching selector 1109 is turned on, aside from some voltage drop across the threshold switching selector 1109. Initially, though, the threshold switching selector 1109 needs to be turned on by applying a voltage above the threshold voltage Vth of the threshold switching selector 1109, and then the biasing current or voltage needs to be maintained high enough above the holding current or holding voltage of the threshold switching selector 1109 so that it stays on during the subsequent read or write operation.

On the second layer, an MRAM cell 1112 includes free layer 1111, tunnel barrier 1113, and reference layer 1115 is formed above the threshold switching selector 1119, with the series combination of the MRAM device 1112 and the threshold switching selector 1119 together forming the layer 2 cell between the bit line 1110 and word line 2 1120. The layer 2 cell will operate as for the layer 1 cell, although the lower conductor now corresponds to a bit line 1110 and the upper conductor is now a word line, word line 2 1120.

In the embodiment of FIG. 11A, the threshold switching selector 1109/1119 is formed below the MRAM device 1102/1112, but in alternate embodiments the threshold switching selector can be formed above the MRAM device for one or both layers. As discussed with respect to FIGS. 10A and 10B, the MRAM memory cell is directional. In FIG. 11A, the MRAM devices 1102 and 1112 have the same orientation, with the free layer 1101/1111 above (relative to the unshown substrate) the reference layer 1105/1115. Forming the layers between the conductive lines with the same structure can have a number of advantages, particularly with respect to processing as each of the two layers, as well as subsequent layers in embodiments with more layers, can be formed according to the same processing sequence.

FIG. 11B illustrates an alternate embodiment that is arranged similarly to that of FIG. 11A, except that in the layer 2 cell the locations of the reference layer and free layer are reversed. More specifically, between word line 1 1150 and bit line 1160, as in FIG. 11A the layer cell 1 includes an MRAM structure 1152 having a free layer 1151 formed over tunnel barrier 1153, that is turn formed over the reference layer 1155, with the MRAM structure 1152 formed over the threshold switching selector 1159. The second layer of the embodiment of FIG. 11B again has an MRAM device 1162 formed over a threshold switching selector 1169 between the bit line 1160 and word line 2 1170, but, relative to FIG. 11A, with the MRAM device 1162 inverted, having the reference layer 1161 now formed above the tunnel barrier 1163 and the free layer 1165 now under the tunnel barrier 1163.

Although the embodiment of FIG. 11B requires a different processing sequence for the forming of layers, in some embodiments it can have advantages. In particular, the directionality of the MRAM structure can make the embodiment of FIG. 11B attractive since when writing or reading in the same direction (with respect to the reference and free layers) the bit line will be biased the same for both the lower layer and the upper layer, and both word lines will be biased the same. For example, if both layer 1 and layer 2 memory cells are sensed in the P2AP direction (with respect to the reference and free layers), the bit line layer 1160 will be biased such as in the P2AP direction, the bit line 1160 is biased low (e.g., 0V) for both the upper and lower cell, with word line 1 1150 and word line 2 1170 both biased to a higher voltage level. Similarly, with respect to writing, for writing to the high resistance AP state the bit line 1160 is biased low (e.g., 0V) for both the upper and lower cell, with word line 1 1150 and word line 2 1170 both biased to a higher voltage level; and for writing to the low resistance P state the bit line 1160 is biased to the high voltage level, with word line 1 1150 and word line 2 1170 both biased to the low voltage level. In contrast, for the embodiment of FIG. 11A, the bit lines and word lines would need to have their bias levels reversed for performing any of these operations on the upper level relative to the lower level.

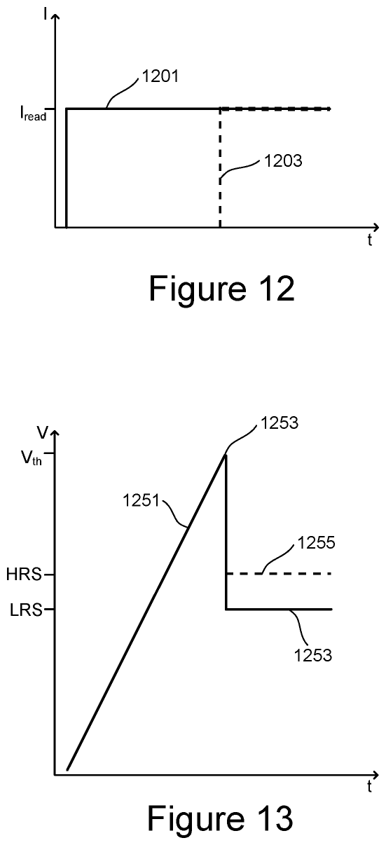

To either read data from or write data to an MRAM memory cell involves passing a current through the memory cell. In embodiments where a threshold switching selector is placed in series with the MRAM device, before the current can pass through the MRAM device the threshold switching selector needs to be turned on by applying a sufficient voltage across the series combination of the threshold switching selector and the MRAM device. FIGS. 12 and 13 consider this activation of the threshold switching selector in more detail in the context of a read operation.

FIGS. 12 and 13 are an embodiment of a set of waveforms respectively for the current and the voltage for the layer 1 cell of FIGS. 11A and 11B in a read operation, where the time axes of FIGS. 12 and 13 are aligned and at the same scale. In this embodiment for a read operation the read is performed in the P2AP direction in which word line 1 1100/1150 is biased high and the bit line 1110/1160 is set low (e.g., 0V) so that the (conventional) current flows upward, passing through the reference layer 1105/1155 before passing through the free layer 1101/1151. (In terms of electron current, as opposed to conventional current, the electron flow will be as illustrated in FIG. 10B.)

In the embodiment of FIGS. 12 and 13, a forced current approach is used, with the memory driven from the reference layer side with a read current, I_{read} from a current source in the driver circuitry for the line. As shown FIG. 12 by the solid line 1201, the current is raised to the I_{read} value and held there for the duration of the current read operation. This current will move the lines supplying the current to the selected memory cell, such as word line 1 1100/1150 for the layer 1 memory cell in FIGS. 11A/B, and also support any leakage in the path. As shown at 1251 in FIG. 13, the voltage across the parallel combination of the threshold switching selector and the resistive MRAM element ramps up as the threshold switching selector is in an off state. Once the voltage across threshold switching selector reaches the threshold voltage Vth of the threshold switching selector at 1253, it will turn on and switch to a low resistance state.

Once the threshold switching selector is in the on state, the I_{read} current will flow through the selected memory cell. This is illustrated by the broken line 1203 of FIG. 12 that resents the current through memory cell, jumping from zero to I_{read} when the threshold switching selector switches on at 1253. As the current level is held fixed at I_{read}, the voltage across the memory cell will drop to a level dependent upon the series resistance of the MRAM device and the on-state resistance of the threshold switching selector. For a binary embodiment, the memory cell will have a high resistance anti-parallel state and a low resistance parallel state. The resultant voltage across the series connected MRAM device and threshold switching selector and series decode transistors directing the current into 1 of N word lines and 1 of N bit lines in response to the I_{read} current for the high resistance state (HRS) and low resistance state (LRS) are respectively shown as 1255 and 1253. The resultant voltage difference can then be measured by a sense amplifier to determine the data state stored in the memory cell. Although the discussion here is in the context of an MRAM based memory cell being placed in series with the threshold switching selector, this read technique can similarly be applied to other programmable resistance memory cells, such as PCM, FeRAM, or ReRAM devices.

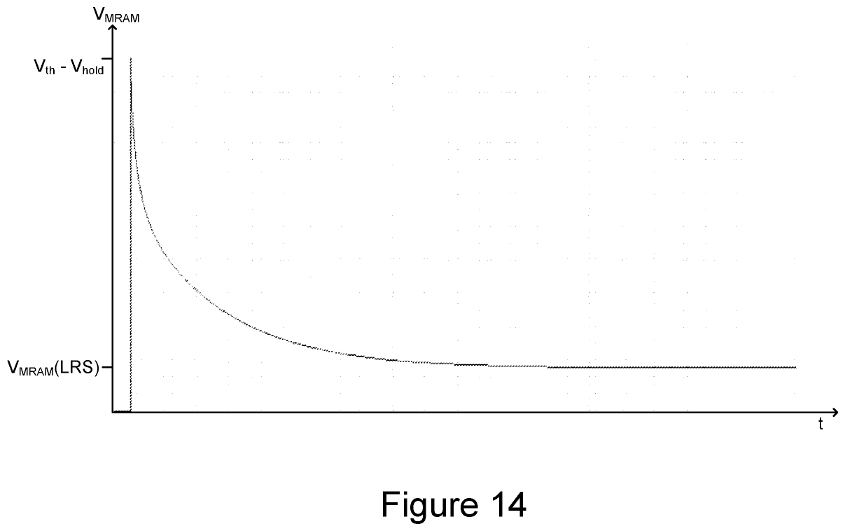

FIG. 13 shows the voltage applied to the ramping up at 1251 until it reaches Vth at 1253, then dropping down to either the high resistance state (HRS) level at 1255 or the low resistance state (LRS) at 1253. In an actual device, due to resistance and capacitances, there will be some delay as the voltage spike at 1253 drops down to either 1255 or 1253. This is illustrated by FIG. 14 for the example of a low resistance state.

FIG. 14 shows an example of the voltage across the MRAM device as the threshold switching selector switches from an off state to an on state. Relative to FIG. 13, FIG. 14 shows the voltage V_{MRAM} across just the MRAM device, while FIG. 13 represents the voltage across the series combination of the threshold switching selector and the MRAM device. Initially, before the threshold switching selector turns on, the voltage across the MRAM device will be zero as the applied voltage ramps up to the Vth voltage. Once the threshold switching selector turns on, current begins to flow through the MRAM device and the voltage across the MRAM device will spike to the Vth level, less the voltage Vhold dropped across the threshold switching selector. Consequently, V_{MRAM} will jump from 0V to ΔV=(Vth−Vhold), after which it will decay down to the voltage drop across the MRAM device in the low resistance state in response to the applied Iread, V_{MRAM}(LRS).

The rate at which the VMRAM voltage drops down to near the asymptotic V_{MRAM}(LRS) level depends on size of the spike from the “snapback voltage” ΔV, which is the difference between (Vth−Vhold) and V_{MRAM}(LRS), and the rate at which charge can flow out of the device, which depends upon the internal resistance of the MRAM and selector when selector is turned on, the R-C characteristics of the memory cell and of the lines between which it is connected (e.g., a word line from a word line driver to the memory cell and a bit line from a bit line driver to the memory cell). Dissipation is faster for lower capacitance and lower resistance. This behavior has some practical consequences for the operation of the memory cell.

A first consequence is that both the low resistance state and the high resistance state will decay as shown in FIG. 14, where FIG. 14 shows the low resistances state. The high resistance state will show similar behavior, but with a higher asymptotic state Vfinal determined by the path resistance x the Iread. In order to distinguish between these two states, they need to be separated by a sufficient margin, so that a sensing operation cannot be performed until after enough time has passed in order for the two states to have well-defined and differentiable voltage levels.

Another consequence is that a spike can disturb the data stored in the memory cell. As discussed with respect to FIGS. 10A and 10B, the state of an MRAM memory can be changed by passing a current through the memory cell, so that if the voltage across and/or current through a memory cell is high enough for long enough, it will, depending on the current's direction, change a parallel state to an anti-parallel state (a P2AP write), as illustrated in FIG. 10B, or change an anti-parallel state to a parallel state (an AP2P write), as illustrated in FIG. 10A. For example, the read process of FIGS. 12 and 13 is described as performed in the P2AP direction, so that a disturb by the waveform of FIG. 14 could switch a low resistance state memory cell to the high resistance state before the data state can be stored.

FIG. 15 shows an example of the current, Icell, through the MRAM device as the threshold switching selector switches from an off state to an on state (current plot corresponding to the voltage plot of FIG. 14). Relative to FIG. 12, FIG. 14 shows the current through just the MRAM device, while FIG. 12 represents the current requested from a driver (e.g., current through the series combination of a word line, a bit line, the threshold switching selector and the MRAM device). Initially, before the threshold switching selector turns on, the current through the MRAM device will be zero (or near zero) as the applied voltage ramps up to the Vth voltage. A word line and/or bit line to the memory cell may become charged up during this time. Once the threshold switching selector turns on, a relatively high current, which may be referred to as the “snapback current” or “Isb,” flows through the MRAM device as parasitic capacitors formed between word and/or bit lines discharge. The rate of discharge may depend on a number of factors including the resistances and capacitances of word and/or bit lines connected to the memory cell.

FIG. 15 shows two curves corresponding to different snapback currents experienced by different memory cells in the same memory array. A first curve 1562 shows a first snapback current, Isb1, while the second curve 1560 shows a second snapback current, Isb2, which is less than Isb1. Also, first curve 1562 shows a slower decay time (t1) than the decay time (t2) of the second curve 1562. The snapback current and corresponding snapback current decay time may vary between memory cells in the same array, which may have certain consequences. For example, higher snapback currents and longer current decay times (e.g., first curve 1562) may cause more disturbance and more errors (e.g., higher Bit Error Rate or “BER”) than memory cells with lower snapback currents and shorter decay times (e.g., second curve 1560).

Snapback currents and decay times may be affected by various factors including the dimensions of lines that connect a memory cell to respective drivers. For example, lines (e.g., word and/or bit lines) have series resistance that depends on their dimensions (e.g., may increase in proportion to length). Lines (e.g., word and/or bit lines) also have some capacitance (e.g., parasitic capacitors formed with neighboring lines) which may increase with length. Word line and bit line drivers may be connected to different memory cells in an array by lines of different length (e.g., some memory cells are near to word line and/or bit line drivers (near cells) than other memory cells (far cells). The different geometry of such lines may affect snapback current and snapback current decay time for different memory cells in an array and may thereby affect error rates.

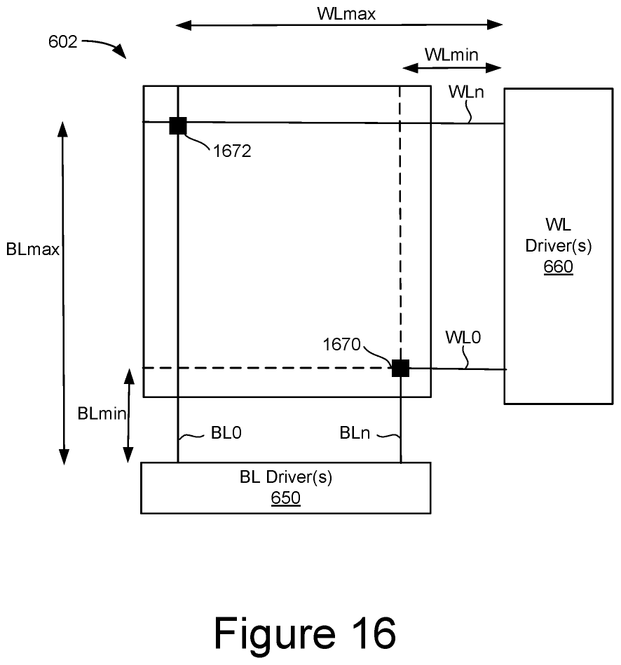

FIG. 16 illustrates an example of memory structure 602 and corresponding word line driver(s) 660 and bit line driver(s) 650 (word line drivers 660 and bit line drivers 650 may be on a memory die with memory structure 602 or on a separate die that is connected to the memory die containing memory structure 602). Two bit lines, BL0 and BLn, and two word lines, WL0 and WLn are illustrated along with first memory cell 1670 and second memory cell 1672 (additional lines and memory cells are omitted for clarity). First memory cell 1670 (near memory cell) is relatively near to both word line driver(s) 660 and bit line driver(s) 650. First memory cell 1670 is connected to bit line driver(s) 650 by BLn, with an effective bit line length of BLmin, and is connected to word line driver(s) 660 by WL0, with an effective word line length of WLmin. This gives a combined electrical distance (effective word line and bit line lengths combined) of BLmin+WLmin. Second memory cell 1672 (far memory cell) is relatively far from both word line driver(s) 660 and bit line driver(s) 650. Second memory cell 1672 is connected to bit line driver(s) 650 by BL0, with an effective bit line length of BLmax, and is connected to word line driver(s) 660 by WLn, with an effective word line length of WLmax. This gives a combined electrical distance (effective word line and bit line lengths combined) of BLmax+WLmax. Because of the different electrical distances and their associated resistance and capacitance, first memory cell 1670 and second memory cell 1672 may have different snapback currents, Isb, and different snapback current decay times (e.g., first memory cell 1670 may have higher snapback current and longer snapback current decay time like first curve 1562 compared with second memory cell 1672, which may have characteristics like second curve 1560). As a result of these differences and/or for any other reasons, data read from first memory cell 1670 and second memory cell 1672 may have different error rates (e.g., data from first memory cell 1670 may have a higher BER than data from second memory cell 1672). While certain examples may refer to mitigating snapback-related effects, aspects of the present technology are not limited to such applications and the present technology may be applied to mitigate other effects (e.g., effects that may generate errors that are non-uniform across a die).

First memory cell 1670 and second memory cell 1672 represent cases at either end of a range of possible electrical distances for memory cells of memory structure 602 to bit line and word line drivers. Other memory cells may have electrical distances somewhere within this range, with corresponding snapback currents and snapback current decay times that are between those of first memory cell 1670 and second memory cell 1672, which may result in error rates between those of first memory cell 1670 and second memory cell 1672. The effects of snapback currents on some or all memory cells may be at least partially predictable based on the electrical distances of the memory cells (e.g., based on respective distances to word line and bit line drivers).

In some memory systems, data from different arrays (e.g., on different memory dies) may be read in parallel and may be combined for ECC decoding. Such parallel operation may provide high throughput and allow an ECC codeword to be distributed across multiple arrays.

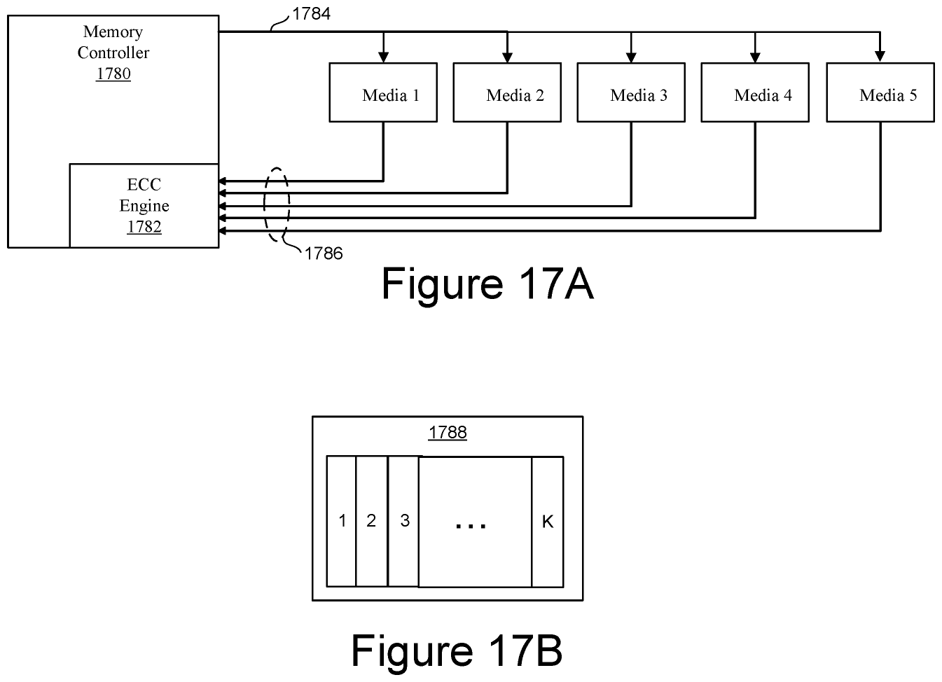

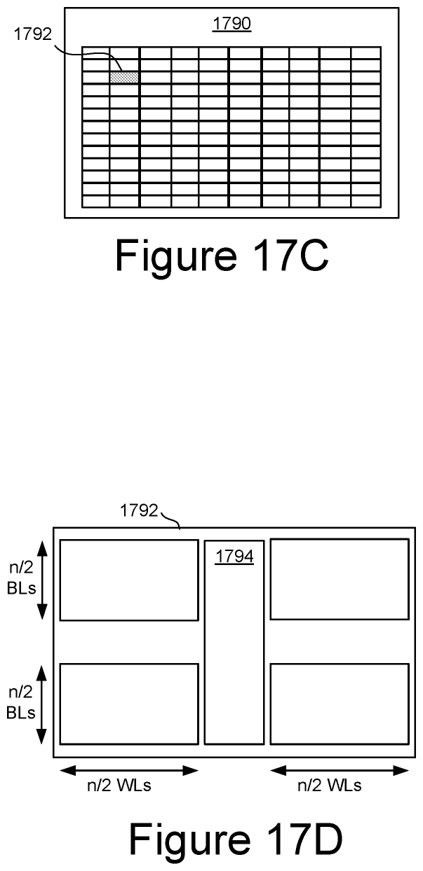

FIG. 17A illustrates an example of an arrangement that includes 5 media, Media 1-Media 5 connected to a memory controller 1780, which includes an ECC engine 1782. For example, each of Media 1-5 may be a memory package 104 (e.g., as shown in FIG. 1), a memory die 292 (as shown in FIG. 4) or integrated memory assembly 600 (e.g., as shown in FIGS. 6A-B) connected to a controller. In the example of FIG. 17A, Media 1-5 are connected to memory controller 1780 through communication channels including an address communication channel 1784 and data communication channels 1786 (e.g., channels of memory bus 294). Address communication channel 1784 is shared by Media 1-5 (common communication channel) while data communication channels 1786 are dedicated communication channels with one data communication channel (e.g., x bits wide, where x can be any suitable number, such as 16, 32, 64, 128 or more) per media.

In an example of a read operation, memory controller 1780 sends a read address to Media 1-5, via address communication channel 1784, specifying an address (or addresses) to be read (target address). Because address communication channel 1784 is common to Media 1-5, each of Media 1-5 receives the same address. Media 1-5 may read data in response to the read command and send the data, via data communication channels 1786, to ECC engine 1782 (e.g., ECC engine 226/256) in memory controller 1780. In this example, each media sends x bits at a time. Media 1-5 may read and send data in parallel so that ECC engine 1782 receives 5x bits of data in parallel (e.g., 4x-bits of user data and x-bits of ECC data). ECC engine 1782 may perform ECC correction on the received 5x bits together (e.g., ECC engine 1782 may be configured to have a codeword size of 5x bits). In other examples, different amounts of data may be sent from a different number of media (e.g., more or fewer than 5) and ECC engine 1782 may be configured to encode/decode using an appropriately sized codeword.

In an example of a write operation, memory controller 1780 sends a write address to Media 1-5, via address communication channel 1784, specifying an address (or addresses) to be written (target address). ECC engine 1782 may generate an ECC codeword of 5x bits (e.g., may receive 4x bits of user data and generate a 5x bit codeword) and may send x bits, via data communication channels 1786, to each of Media 1-5. Media 1-5 may each write respective x bits in response.

FIG. 17B-D show an example structure of a media 1788 (e.g., any of Media 1-5). FIG. 17B shows Media 1788 including K banks (1-K, where K may be any suitable number such as 8, 16, 32, 64 or more).

FIG. 17C shows an example structure of a bank 1790 (e.g., any of banks 1-K of FIG. 17B), which includes x active modules including example module 1792 (shaded). Modules are configured to be read in parallel and for transmission of data in parallel to enable reading and sending of x bits in parallel from modules of a selected bank.

FIG. 17D shows an example structure of module 1792 that includes n bit lines (two sets of n/2 bit lines “n/2 BLs”) and n word lines (two sets of n/2 bit lines each “n/2 WLs”), e.g., in an arrangement such as previously shown in FIGS. 7A-D. While the number of word bit lines and word lines are equal in FIG. 16 and in this example (n bit lines and n word lines), in other examples, these numbers may be different. Module 1792 also includes driver circuits 1794 (e.g., word line driver circuits 660 and/or bit line driver circuits 650), which in this example are shown located in the middle of module 1792, with portions of a memory array on either side. Driver circuits may be located under a memory array in some cases. In some cases, driver circuits are in multiple locations (e.g., some driver circuits located under a memory array, and some located between portions of a memory array or in a peripheral area of an array. Metal connections between driver circuits and array components (e.g., word lines and bit lines) may extend horizontally and/or vertically. In some cases, driver circuits are located on a separate die from a memory die (e.g., in an integrated memory assembly). The present technology is not limited to driver circuits in any particular location. Some logic circuits associated with driver circuits may be located with driver circuits (e.g., module 1792 may include some logic circuits to control driver circuits 1794).

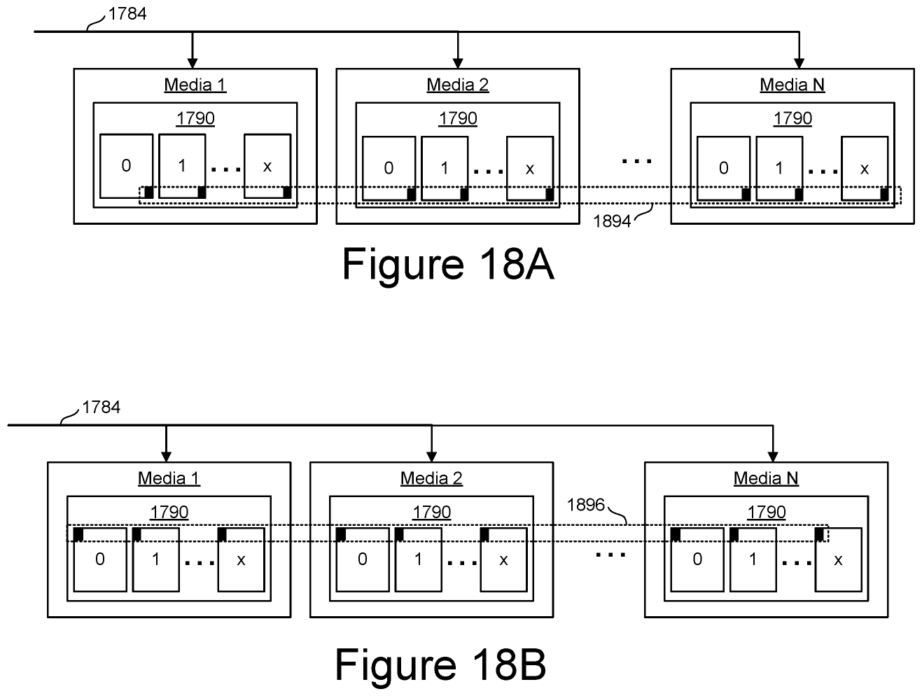

FIG. 18A shows a first example of a read operation directed to N Media (e.g., Media 1-5 of FIG. 17A). A read command may specify a selected bank 1790 and a selected memory cell (e.g., intersection of a selected word line and a selected bit line). In each media, the specified memory cell of each module of the selected bank 1790 is read in parallel. In the example of FIG. 18A, the specified memory cell is shown in the bottom right corner (shaded) of each module 0-x in selected bank 1790 of each of Media 1-N. This location may correspond to the location of first memory cell 1670 (near memory cell) shown in FIG. 16 so that data read from these memory cells may have a relatively high error rate. Data bits 1894 read in the example of FIG. 18A (x bits from each of Media 1-N) may be sent in parallel to ECC circuits (e.g., ECC engine 1782) where they are decoded together as a unit (ECC codeword), which may have a relatively high error rate and therefore a relatively high probability of UE.

FIG. 18B shows another example of a read operation directed to the N media of FIG. 18A. In this example, the read command specifies a different memory cell (intersection of a different word line and bit line). In each media, the specified memory cell of each module of the selected bank 1790 is read in parallel. In the example of FIG. 18B, the specified memory cell is shown in the top left corner (shaded) of each module 0-x in selected bank 1790 of each of Media 1-N. This location may correspond to the location of second memory cell 1672 (far memory cell) shown in FIG. 16 so that data read from these memory cells may have a relatively low error rate. Data bits 1896 read in the example of FIG. 18B (x bits from each of Media 1-N) may be sent in parallel to ECC circuits (e.g., ECC engine 1782) where they are decoded together as a unit (ECC codeword), which may have a relatively low error rate and therefore a relatively low probability of UE.

Aspects of the present technology are directed to accessing data in MRAM structures such that the error rate (e.g., BER) and the probability of UE in any portions of data that are read together and subject to ECC decoding together are managed to mitigate ECC nonuniformity (e.g., nonuniformity shown in the examples of FIG. 18A). For example, data to be ECC decoded as a unit may be stored and subsequently read from different respective locations in different media and/or in different locations in different modules of a media and/or locations that are otherwise non-uniform.

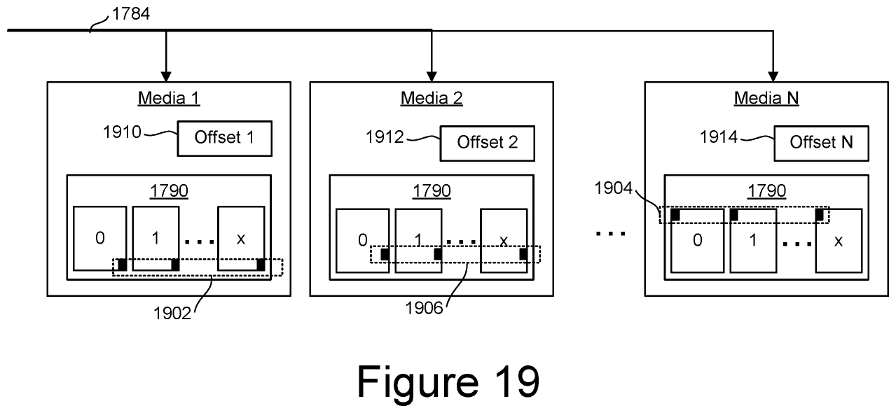

FIG. 19 shows an example of a read operation in which control circuits (e.g., system control logic 560/659) of each of Media 1-N applies a different offset to a read address received via address communication channel 1784 to generate respective offset addresses (where the number of media, N, may be any suitable number, e.g., 2, 4, 8, 16 or more). For example, Media 1 may apply a first offset (Offset 1) that causes reading of memory cells in the bottom right of memory modules 1-x of selected bank 1790 (similar to FIG. 18A) to obtain data 1902 (every module 1-x is read at the same respective location in parallel). Media N may apply an Nth offset (Offset N) that causes reading of memory cells in the top left of memory modules 1-x of selected bank 1790 (similar to FIG. 18B) to obtain data 1904. Media 2 to Media N−1 may apply other offsets to cause reading of memory cells at intermediate locations to obtain additional data (e.g., Offset 2 in Media 2 to obtain data 1906). The individual address offset used in each media may include at least one of a word line offset and/or a bit line offset that causes reading of modules of different media at different locations (modules of a selected bank in any given media are read at a common offset address in this example). Data from all media 1-N (including data 1902, 1904 and 1906) may be read in parallel and may be sent in parallel to ECC circuits where it is decoded. Because the data comes from different respective locations in different media, the combined data may have an error rate that is intermediate (e.g., between the error rates of the examples of FIGS. 18A and 18B) and may represent an average error rate for the different locations across the array. Errors rates may be relatively uniform across different code words (e.g., compared with reading all data of a codeword from the same location in all media as in FIGS. 18A-B) so that the probability of UE is relatively low.

While FIG. 19 shows an example of a read operation, write operations may use the same offsets so that a codeword generated by ECC encoding is spread across different locations in different media. For example, data 1902, 1904, 1906 and any additional portions of data from Media 3 to N−1 may be portions of an ECC codeword that are written at the locations shown in parallel.

The scheme of FIG. 19 may be implemented by having control circuits with an offset register in each media that records a corresponding individual address offset, with different media having different address offsets (e.g., each media 1-N having a different address offset value stored in a register of respective control circuits). Offset address values may be selected based on the number of media and the number of memory cells in a module (e.g., the number of cells may be divided by the number of media so that offsets cause accessing memory cells of different media at locations that are equally spaced apart from each other). A memory controller (e.g., controller 102) may determine how many media (e.g., memory dies) are present in the system and may configure an offset register of each die in order to spread out the addresses uniformly (e.g., so that increasing the number of dies would reduce the offset in proportion to the inverse of the number of dies). For example, FIG. 19 shows Media 1 having control circuits 1910 including an offset register (e.g., register 561) that stores Offset 1, Media 2 having control circuits 1912 that includes an offset register that stores Offset 2 and Media N having control circuits 1914 that include an offset register that stores Offset N. Address offsets may be set during configuration of a memory system in a one-time operation or may be reconfigurable during the working life of the memory system. Control circuits of Media 1-N (including control circuits 1910, 1912 and 1914) may be configured to receive a read address from a memory controller in parallel (e.g., via common address communication channel 1784) apply the respective individual address offsets to the read address to generate respective offset addresses, read portions of data from the respective offset addresses (e.g., data 1902, 1906 . . . 1904) and send the data read from the offset addresses to a memory controller to perform Error Correction Code (ECC) decoding of the portions of data.

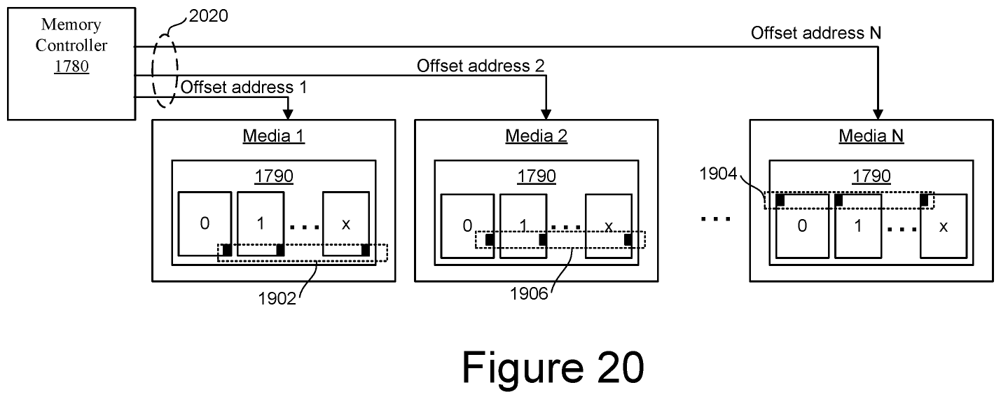

FIG. 20 illustrates another read operation in which data is stored and read from offset addresses to provide an ECC codeword that includes data from a range of locations. In the example of FIG. 20, offsets are applied, and respective offset addresses are generated by memory controller 1780. In this example, Media 1 to Media N do not apply an offset and may not include an offset register as in the previous example. Each media receives a different offset address from memory controller 1780. For example, Media 1 receives Offset address 1, Media 2 receives offset address 2 and Media N receives offset address N. In this example, dedicated communication channels 2020 are used to provide different offset addresses to each media to cause reading of data from the respective offset addresses (one address communication channel per media to enable sending different offset addresses in parallel). The data from the different respective locations is then sent to the ECC engine for decoding as a unit as before.

In another example, instead of dedicated communication channels 2020, a common address communication channel (e.g., address communication channel 1784) may be used to send different addresses (e.g., in series) to different media (e.g., control circuits in each media may parse a command such as a read or write command to determine whether they are the destination for the command).

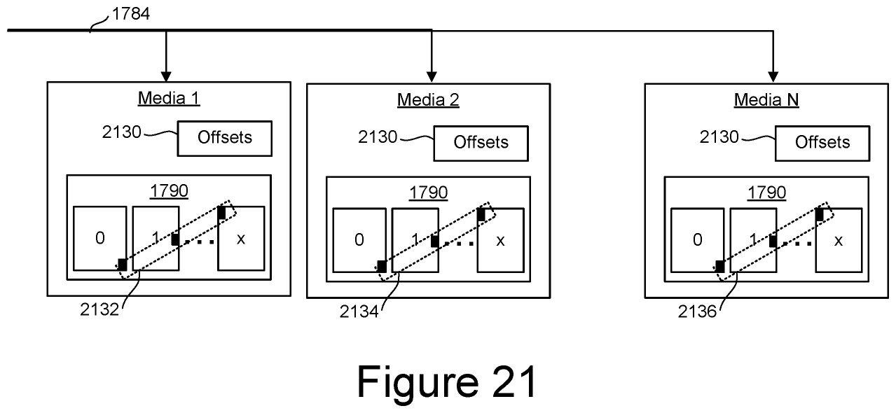

FIG. 21 illustrates another read operation in which data is stored and read from offset address to provide an ECC codeword that includes data from a range of locations. In the example of FIG. 21, offsets are applied on a module-by-module basis within selected banks of each media. For example, in Media 1, modules 0-x of selected bank 1790 are accessed at different locations that are indicated by offsets stored in registers 2130. A memory cell in the bottom right of module 0 is read in parallel with a memory cell in the top left of module x and intermediate memory cells in modules 1 to N−1. The data 2132 read from these memory cells comes from memory cells at different locations with respect to word line and bit line drivers and may have an error rate that is an average of error rates for different locations within a module. Similarly, in each of Media 2 to Media N, data in the selected bank 1790 is read from different locations in different modules and may have an error rate that is an average of error rates for different locations within a module. Data 2132 from Media 1, data 2134 from Media 2-data 2136 from Media N may be read in parallel and may be sent to an ECC engine in parallel for decoding together.

Because data is read from a range of locations within each media, data from each media may have a similar error rate. Each media may apply a similar set of offsets so that reading patterns may be the same for all media. Each media includes a set of registers 2130 that stores offsets to apply when writing and reading data. In some cases, where different bits are sampled in each module, registers 2130 may be unnecessary. In one example, a different offset is applied to each module. In another example, modules are grouped with a different offset for each group (e.g., x modules may be grouped into four groups of x/4 modules each, with each group having a respective offset for a total of four offsets in registers 2130). In some cases, offsets of different media may be different (e.g., aspects of module-by-module offsets may be combined with media-by-media offsets).

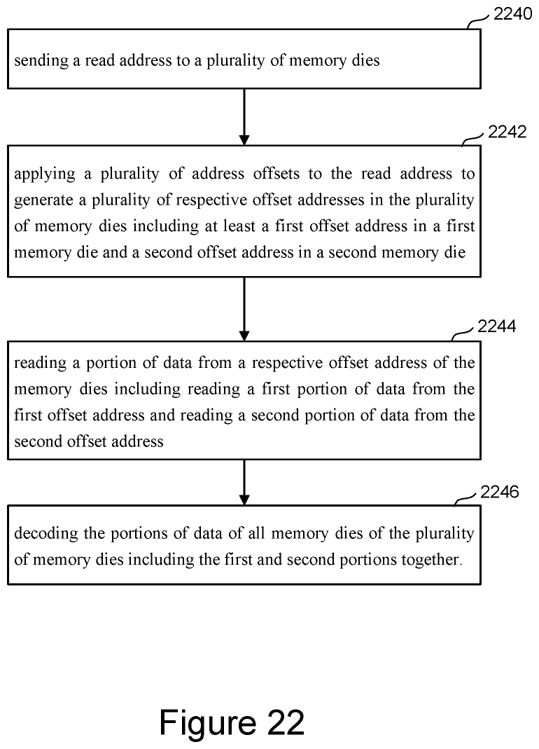

FIG. 22 illustrates an example of a method according to aspects of the present technology. The method includes sending a read address to a plurality of memory dies 2240, applying a plurality of address offsets to the read address to generate a plurality of respective offset addresses in the plurality of memory dies including at least a first offset address in a first memory die and a second offset address in a second memory die 2242. The method further includes reading a portion of data from a respective offset address of the memory dies including reading a first portion of data from the first offset address and reading a second portion of data from the second offset address 2244; and decoding the portions of data of all memory dies of the plurality of memory dies including the first and second portions together 2246.

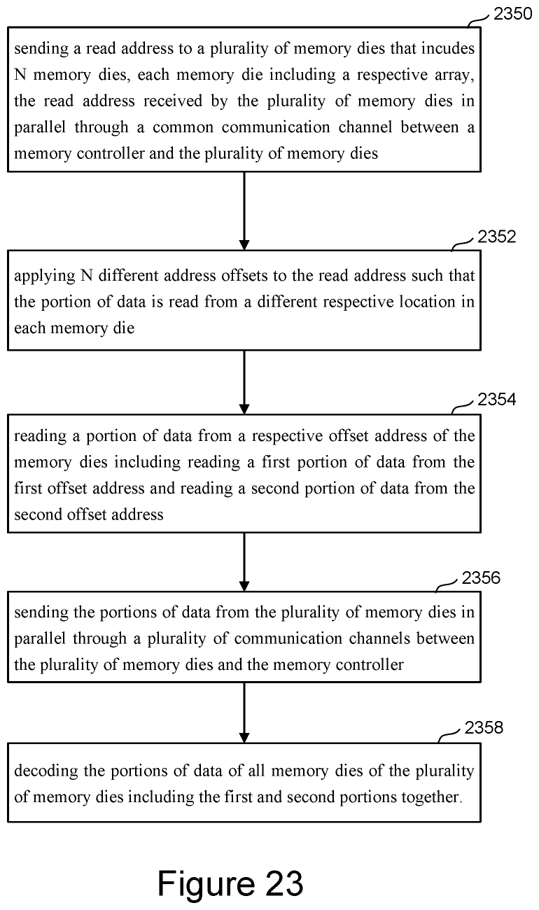

The method of FIG. 22 may be implemented in various ways according to aspects of the present technology. FIG. 23 illustrates an example implementation that includes sending a read address to a plurality of memory dies that incudes N memory dies, each memory die including a respective array, the read address received by the plurality of memory dies in parallel through a common communication channel between a memory controller and the plurality of memory dies 2350 (e.g., the N media of FIG. 19 or 21 receiving the same read address via address communication channel 1784) and applying N different address offsets to the read address such that the portion of data is read from a different respective location in each memory die 2352 (e.g., as illustrated by data 1902, 1904 and 1906 in FIGS. 19-20 or data 2132, 2134 and 2136 in FIG. 21). The method further includes reading a portion of data from a respective offset address of the memory dies including reading a first portion of data from the first offset address (e.g., data 1902) and reading a second portion of data from the second offset address (e.g., data 1904) 2354, sending the portions of data from the plurality of memory dies in parallel through a plurality of communication channels between the plurality of memory dies and the memory controller 2356 (e.g., data communication channels 1786 between Media 1-5 and memory controller 1780 of FIG. 17A) and decoding the portions of data of all memory dies of the plurality of memory dies including the first and second portions together 2358 (e.g., ECC engine 1782 decoding portions of data including data 1902 and 1904 together as a codeword).

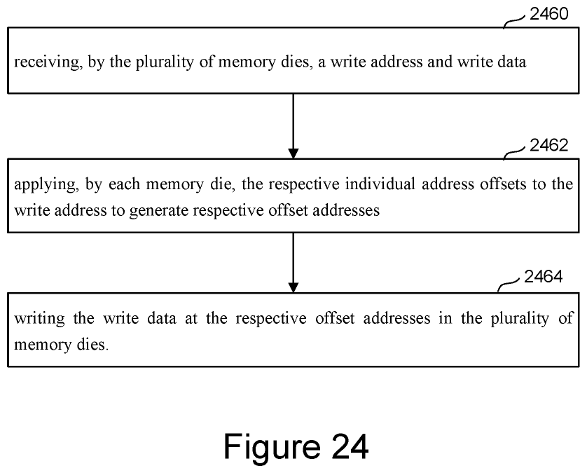

Offsets (e.g., individual die-specific, module-specific, or other offsets) may be used for all memory access including read access (e.g., as illustrated in FIG. 22 or 23) and write access. While examples above are described with respect to read operations and subsequent ECC decoding of data read using offsets, write operations may use offsets so that data to be written is ECC encoded and subsequently written at different locations according to offsets (e.g., offsets of the examples of FIGS. 19-21). FIG. 24 shows an example of a method that uses offset addresses when writing (e.g., writing data that is subsequently read as illustrated in FIG. 22 or 23). The method of FIG. 24 may be implemented in any suitable memory system, for example, a memory system that includes multiple media as illustrated in the examples of FIGS. 17A-D.

FIG. 24 illustrates an example of a method that includes receiving, by the plurality of memory dies (e.g., Media 1-N of FIGS. 19-21), a write address and write data 2460, applying, by each memory die (e.g., each of Media 1-N), the respective individual address offsets (e.g., Offset 1-N) to the write address to generate respective offset addresses 2462 and writing the write data at the respective offset addresses in the plurality of memory dies 2464 (e.g., writing data at the same offset addresses that may later be used when reading the data, for example, as illustrated by data 1902, 1904 and 1906 in FIGS. 19-20 or data 2132, 2134 and 2136 of FIG. 21).

According to a first set of aspects, an apparatus includes a plurality of control circuits configured to individually connect to arrays that each include a plurality of non-volatile memory cells. Each non-volatile memory cell includes a programmable resistive element. Each control circuit is configured with an individual address offset. The plurality of control circuits are configured to: receive a read address from a memory controller in parallel; apply the respective individual address offsets to the read address to generate respective offset addresses; read portions of data from the respective offset addresses; and send the data read from the offset addresses to the memory controller to perform Error Correction Code (ECC) decoding of the portions of data.

The plurality of control circuits may include at least a first control circuit configured to connect to a first array and a second control circuit configured to connect to a second array, the first control circuit configured with a first address offset, the second control circuit configured with a second address offset such that a first offset address generated by applying the first address offset is closer to at least one of a word line driver or a bit line driver than a second offset address generated by applying the second address offset. The first control circuit and the first array may be located on a first die and the second control circuit, and the second array may be located on a second die. The first control circuit may be located on a first control die configured to be bonded to a first memory die containing the first array and the second control circuit may be located on a second control die configured to be bonded to a second memory die containing the second array. The plurality of control circuits may include N control circuits each connected to a respective array, the N control circuits applying N different address offsets. The N different address offsets may be configured to cause reading each array at a different respective location with respect to at least one of a word line driver or a bit line driver. The N different address offsets may be configured to cause reading each array at different respective locations that are equally spaced apart from each other. Each array may include a plurality of banks, each bank may include a plurality of modules that are configured to be read in parallel and the individual address offset may include at least one of a word line offset or a bit line offset that causes reading of every module of a bank indicated by the read command at a common offset address. Each array may include a plurality of banks, each bank may include a plurality of modules that are configured to be read in parallel and the individual address offset may cause reading of different modules of a bank indicated by the read command at different offset addresses. Each control circuit may include a register to store a corresponding individual address offset.

In another set of aspects, a method includes sending a read address to a plurality of memory dies, applying a plurality of address offsets to the read address to generate a plurality of respective offset addresses in the plurality of memory dies including at least a first offset address in a first memory die and a second offset address in a second memory die, reading a portion of data from a respective offset address of the memory dies including reading a first portion of data from the first offset address and reading a second portion of data from the second offset address; and decoding the portions of data of all memory dies of the plurality of memory dies including the first and second portions together.

The plurality of memory dies may include N memory dies, each memory die including a respective array, the N memory dies applying N different address offsets such that the portion of data is read from a different respective location in each memory die. The read address may be received by the plurality of memory dies in parallel through a common communication channel between a memory controller and the plurality of memory dies. The portions of data from the plurality of memory dies may be sent in parallel through a plurality of communication channels between the plurality of memory dies and the memory controller. The method may further include receiving, by the plurality of memory dies, a write address and write data; applying, by each memory die, the respective individual address offsets to the write address to generate respective offset addresses; and writing the write data at the respective offset addresses in the plurality of memory dies. The method may further include selecting the respective individual address offsets according to the number of memory dies and locations of word line and bit line drivers with respect to addresses in the dies. Applying respective individual address offsets to the read address to generate a plurality of respective offset addresses in the plurality of memory dies may include, in a first memory die, applying different address offsets to read different modules of the first memory die in parallel.

In another set of aspects, a system includes an Error Correction Code (ECC) circuit; a first array that includes a plurality of non-volatile memory cells, each non-volatile memory cell comprising a programmable resistive element; means for applying a first address offset to read and write commands from the memory controller directed to a target address to obtain a first offset address, read data from the first offset address in the first array and send data from the first offset address in the first array to the ECC circuit for ECC decoding; a second array that includes a plurality of non-volatile memory cells, each non-volatile memory cell comprising a programmable resistive element; and means for applying a second address offset to read and write commands from the memory controller directed to the target address to obtain a second offset address, read data from the second offset address in the second array and send data from the second offset address in the second array to the ECC circuit for ECC decoding with the data from the first offset address in the first array.

The first offset address may be located a first distance from word line and/or bit line drivers of the first array, the second offset address may be located a second distance from word line and/or bit line drivers of the second array and the first distance may be less than the second distance. The first array and the means for applying the first address offset may be located in a first media, the second array and the means for applying the second address offset may be located in a second media and the ECC circuit may be located in a memory controller die that is connected to the first media, the second media and additional media.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
a plurality of control circuits configured to individually connect to arrays that each include a plurality of non-volatile memory cells, each non-volatile memory cell comprising a programmable resistive element, each control circuit configured with an individual address offset, the plurality of control circuits are configured to:
receive a read address from a memory controller in parallel;
apply the respective individual address offsets to the read address to generate respective offset addresses;
read portions of data from the respective offset addresses; and
send the data read from the offset addresses to the memory controller to perform Error Correction Code (ECC) decoding of the portions of data.

2. The apparatus of claim 1, wherein the plurality of control circuits includes at least a first control circuit configured to connect to a first array and a second control circuit configured to connect to a second array, the first control circuit configured with a first address offset, the second control circuit configured with a second address offset such that a first offset address generated by applying the first address offset is closer to at least one of a word line driver or a bit line driver than a second offset address generated by applying the second address offset.

3. The apparatus of claim 2, wherein the first control circuit and the first array are located on a first die and the second control circuit and the second array are located on a second die.

4. The apparatus of claim 2, wherein the first control circuit is located on a first control die configured to be bonded to a first memory die containing the first array and the second control circuit is located on a second control die configured to be bonded to a second memory die containing the second array.

5. The apparatus of claim 1, wherein the plurality of control circuits includes N control circuits each connected to a respective array, the N control circuits applying N different address offsets.

6. The apparatus of claim 5, wherein the N different address offsets are configured to cause reading each array at a different respective location with respect to at least one of a word line driver or a bit line driver.

7. The apparatus of claim 6, wherein the N different address offsets are configured to cause reading each array at different respective locations that are equally spaced apart from each other.

8. The apparatus of claim 1, wherein each array includes a plurality of banks, each bank includes a plurality of modules that are configured to be read in parallel and the individual address offset includes at least one of a word line offset or a bit line offset that causes reading of every module of a bank indicated by the read command at a common offset address.

9. The apparatus of claim 1, wherein each array includes a plurality of banks, each bank includes a plurality of modules that are configured to be read in parallel and the individual address offset causes reading of different modules of a bank indicated by the read command at different offset addresses.

10. The apparatus of claim 1, wherein each control circuit includes a register to store a corresponding individual address offset.

11. A method, comprising:
sending a read address to a plurality of memory dies applying a plurality of address offsets to the read address to generate a plurality of respective offset addresses in the plurality of memory dies including at least a first offset address in a first memory die and a second offset address in a second memory die;
reading a portion of data from a respective offset address of the memory dies including reading a first portion of data from the first offset address and reading a second portion of data from the second offset address; and
decoding the portions of data of all memory dies of the plurality of memory dies including the first and second portions together.

12. The method of claim 11, wherein the plurality of memory dies includes N memory dies, each memory die including a respective array, the N memory dies applying N different address offsets such that the portion of data is read from a different respective location in each memory die.

13. The method of claim 11, wherein the read address is received by the plurality of memory dies in parallel through a common communication channel between a memory controller and the plurality of memory dies.

14. The method of claim 13, wherein the portions of data from the plurality of memory dies are sent in parallel through a plurality of communication channels between the plurality of memory dies and the memory controller.

15. The method of claim 11, further comprising:
receiving, by the plurality of memory dies, a write address and write data;
applying, by each memory die, the respective individual address offsets to the write address to generate respective offset addresses; and
writing the write data at the respective offset addresses in the plurality of memory dies.

16. The method of claim 11, further comprising selecting the respective individual address offsets according to the number of memory dies and locations of word line and bit line drivers with respect to addresses in the dies.

17. The method of claim 16, wherein applying respective individual address offsets to the read address to generate a plurality of respective offset addresses in the plurality of memory dies includes, in a first memory die, applying different address offsets to read different modules of the first memory die in parallel.

18. A system, comprising:
an Error Correction Code (ECC) circuit;
a first array that includes a plurality of non-volatile memory cells, each non-volatile memory cell comprising a programmable resistive element;
means for applying a first address offset to read and write commands from the memory controller directed to a target address to obtain a first offset address, read data from the first offset address in the first array and send data from the first offset address in the first array to the ECC circuit for ECC decoding;
a second array that includes a plurality of non-volatile memory cells, each non-volatile memory cell comprising a programmable resistive element; and
means for applying a second address offset to read and write commands from the memory controller directed to the target address to obtain a second offset address, read data from the second offset address in the second array and send data from the second offset address in the second array to the ECC circuit for ECC decoding with the data from the first offset address in the first array.

19. The system of claim 18, wherein the first offset address is located a first distance from word line and/or bit line drivers of the first array, the second offset address is located a second distance from word line and/or bit line drivers of the second array and the first distance is less than the second distance.

20. The system of claim 18, wherein the first array and the means for applying the first address offset are located in a first media, the second array and the means for applying the second address offset are located in a second media and the ECC circuit is located in a memory controller die that is connected to the first media, the second media and additional media.
